(19) United States
(12) Patent Application Publication
(10) Pub. No.: US 2024/0135468 A1
(43) Pub. Date: Apr. 25, 2024

(54) Power Consumption Estimation Device, Power Consumption Estimation Method, and Non-transitory Computer Readable Storage Medium Storing Power Consumption Estimation Program

(71) Applicant: Mitsubishi Electric Corporation, Tokyo (JP)

(72) Inventors: Fuyuki SATO, TOKYO (JP); Shinichiro OTANI, TOKYO (JP)

(73) Assignee: Mitsubishi Electric Corporation, Tokyo (JP)

(21) Appl. No.: 18/395,871

(22) Filed: Dec. 26, 2023

Related U.S. Application Data
(63) Continuation of application No. PCT/JP2021/030171, filed on Aug. 18, 2021.

(51) Int. Cl. G06Q 50/06; G06N 7/01; G06Q 10/04

(52) U.S. Cl. CPC G06Q 50/06; G06N 7/01; G06Q 10/04

(57) ABSTRACT

A CPU performs multiple regression analysis using a first regression model to calculate a tentative degree of contribution of each target facility to the total power consumption. The CPU calculates tentative power consumption of the target facility using the tentative degree of contribution of the target facility. The CPU calculates power consumption of a non-monitored facility by subtracting the total value of the tentative power consumption of the target facility from the total power consumption. The CPU classifies time-series data of the power consumption of the non-monitored facility into a plurality of clusters. The CPU performs multiple regression analysis using a second regression model to determine the degree of contribution of each of the target facilities. The CPU determines the power consumption of the target facility using the determined degree of contribution.

### CROSS REFERENCE TO RELATED APPLICATIONS

The present application is a continuation of International application No. PCT/JP2021/030171, filed on Aug. 18, 2021, the entire contents of which are incorporated herein by reference.

### TECHNICAL FIELD

The present disclosure relates to a power consumption estimation device, a power consumption estimation method, and a non-transitory computer readable storage medium storing a power consumption estimation program.

### BACKGROUND ART

In a structure such as a building or a factory, in a case where power is controlled for the purpose of energy saving, it is necessary to grasp power consumption of each of a plurality of electrical facilities installed in the structure. Installing an electricity meter for each electrical facility in order to grasp the power consumption of each electrical facility, however, causes an increase in cost.

Therefore, there has been proposed a technique to estimate the power consumption of each electrical facility by performing regression analysis on the basis of time-series data of total power consumption in a predetermined zone and time-series data indicating operation states of a plurality of electrical facilities installed in the predetermined zone.

For example, Japanese Patent Laying-Open No. 2020-4041 (PTL 1) discloses a power consumption estimation device that estimates power consumption of each target facility by performing multiple regression analysis with the total power consumption throughout a predetermined zone as an objective variable and the operation states of a plurality of electrical facilities installed in the predetermined zone and component values of a plurality of reference signals each represented by a predetermined basis function as explanatory variables. As disclosed in PTL 1, an increase in accuracy of estimating the power consumption of an electrical facility (hereinafter, also referred to as “non-monitored facility”) other than the target facilities installed in the predetermined zone is achieved by means of simulation of the power consumption of the non-monitored facility using the plurality of reference signals. Then, the increase in accuracy of estimating the power consumption of the non-monitored facility also yields an increase in accuracy of estimating the power consumption of each target facility.

### CITATION LIST

### Patent Literature

PTL 1: Japanese Patent Laying-Open No. 2020-4041

### SUMMARY OF INVENTION

### Technical Problem

In the technique disclosed in PTL 1, however, the power consumption of the non-monitored facility is represented by the plurality of reference signals on the assumption that there is only one operation pattern of the non-monitored facility. Therefore, for a non-monitored facility having a plurality of operation patterns, such as a non-monitored facility having operation patterns differing between weekdays and weekends, there is a concern about an increase in error between the power consumption estimated by means of multiple regression analysis and the actual value of the power consumption. As the accuracy of estimating the power consumption of the non-monitored facility decreases, the accuracy of estimating the power consumption of each target facility also decreases.

The present disclosure has been made to solve the above-described problems, and it is therefore an object of the present disclosure to provide a technique to accurately estimate power consumption of each of a plurality of target facilities installed in a predetermined zone.

### Solution To Problem

A power consumption estimation device according to one aspect of the present disclosure estimates power consumption of each of at least one target facility installed in a predetermined zone. The predetermined zone further has a non-monitored facility installed therein. The power consumption estimation device includes a total power consumption acquisition unit, an operation state acquisition unit, a first reference signal generation unit, a contribution degree estimation unit, a power consumption estimation unit, a non-monitored power consumption calculation unit, a clustering unit, and a second reference signal generation unit. The total power consumption acquisition unit acquires time-series data of total power consumption that is power consumption throughout the predetermined zone. The operation state acquisition unit acquires time-series data of an operation parameter obtained by quantifying an operation state of the at least one target facility. The first reference signal generation unit generates at least one first reference signal. The contribution degree estimation unit performs multiple regression analysis using a first regression model with the acquired total power consumption as an objective variable and the acquired operation parameter and the at least one first reference signal as explanatory variables to calculate a tentative degree of contribution of each of the at least one target facility to the total power consumption. The power consumption estimation unit calculates tentative power consumption of the target facility by multiplying the tentative degree of contribution of the target facility by the operation parameter. The non-monitored power consumption calculation unit calculates time-series data of power consumption of the non-monitored facility by subtracting the total value of the tentative power consumption of the at least one target facility from the time-series data of the total power consumption. The clustering unit divides the time-series data of the power consumption of the non-monitored facility into a plurality of waveforms at predetermined time intervals and classify the plurality of waveforms into a plurality of clusters on the basis of a degree of similarity between the waveforms. The second reference signal generation unit generates a plurality of second reference signals corresponding, on a one-to-one basis, to the plurality of clusters. The contribution degree estimation unit performs multiple regression analysis using a second regression model with the total power consumption as an objective variable and the operation parameter and the plurality of second reference signals as explanatory variables to determine the degree of contribution of each of the at least one target facility to the total power consumption. The power consumption estimation unit determines the power consumption of the target facility by multiplying the determined degree of contribution of the target facility by the operation parameter.

A power consumption estimation method according to another aspect of the present disclosure is a power consumption estimation method for estimating power consumption of each of at least one target facility installed in a predetermined zone. The predetermined zone further has a non-monitored facility installed therein. The power consumption estimation method includes acquiring time-series data of total power consumption that is power consumption throughout the predetermined zone, acquiring time-series data of an operation parameter obtained by quantifying an operation state of the at least one target facility, generating a first reference signal, performing multiple regression analysis using a first regression model with the acquired total power consumption as an objective variable and the acquired operation parameter and the first reference signal as explanatory variables to calculate a tentative degree of contribution of each of the at least one target facility to the total power consumption, calculating tentative power consumption of the target facility by multiplying the tentative degree of contribution of the target facility by the operation parameter, calculating time-series data of power consumption of the non-monitored facility by subtracting a total value of the tentative power consumption of the at least one target facility from the time-series data of the total power consumption, dividing the time-series data of the power consumption of the non-monitored facility into a plurality of waveforms at predetermined time intervals and classifying the plurality of waveforms into a plurality of clusters on the basis of a degree of similarity between the waveforms, generating a plurality of second reference signals corresponding, on a one-to-one basis, to the plurality of clusters, performing multiple regression analysis using a second regression model with the total power consumption as an objective variable and the operation parameter and the plurality of second reference signals as explanatory variables to determine the degree of contribution of each of the at least one target facility to the total power consumption, and determining the power consumption of the target facility by multiplying the determined degree of contribution of the target facility by the operation parameter.

A power consumption estimation program according to another aspect of the present disclosure causes a computer to execute each step of the power consumption estimation method.

### Advantageous Effects of Invention

According to the present disclosure, it is possible to accurately estimate the power consumption of each of the plurality of target facilities installed in the predetermined zone.

### BRIEF DESCRIPTION OF DRAWINGS

FIG. 1 is a diagram illustrating a hardware configuration of a power consumption estimation device according to a first embodiment.

FIG. 2 is a block diagram illustrating a functional configuration of the power consumption estimation device according to the first embodiment.

FIG. 3 is a diagram for describing a first regression model.

FIG. 4 is a graph showing changes over time in power consumption of a target facility and non-monitored power consumption estimated by means of multiple regression analysis using the first regression model.

FIG. 5 is a diagram for describing the concept of redefinition of the non-monitored power consumption.

FIG. 6 is a diagram for describing total power consumption.

FIG. 7 is a diagram for describing the non-monitored power consumption.

FIG. 8 is a diagram for describing clustering processing performed by a clustering unit.

FIG. 9 is a diagram illustrating an example of a clustering result.

FIG. 10 is a diagram illustrating a pattern selection matrix generated from the clustering result illustrated in FIG. 9.

FIG. 11 is a diagram for describing a second regression model.

FIG. 12 is a graph showing power consumption of the target facility and non-monitored power consumption estimated by means of multiple regression analysis using the second regression model.

FIGS. 13A, 13B and 13C are diagrams illustrating a result of comparison between the first embodiment and a conventional technique.

FIG. 14 is a flowchart illustrating an example of a flow of power consumption estimation processing performed by the power consumption estimation device according to the first embodiment.

FIG. 15 is a flowchart illustrating a detailed process flow of step S100 in FIG. 14.

FIG. 16 is a flowchart illustrating a detailed process flow of step S500 in FIG. 15.

FIG. 17 is a block diagram illustrating a functional configuration of a power consumption estimation device according to a second embodiment.

FIG. 18 is a flowchart illustrating an example of a flow of power consumption estimation processing performed by the power consumption estimation device according to the second embodiment.

FIG. 19 is a flowchart illustrating a detailed process flow of step S600 in FIG. 18.

FIG. 20 is a block diagram illustrating a functional configuration of a power consumption estimation device according to a third embodiment.

### DESCRIPTION OF EMBODIMENTS

Embodiments of the present disclosure will be described in detail with reference to the drawings. Note that the same or corresponding parts in the drawings are denoted by the same reference numerals to avoid the description from being redundant.

### First Embodiment

### <Configuration of Power Consumption Estimation Device>

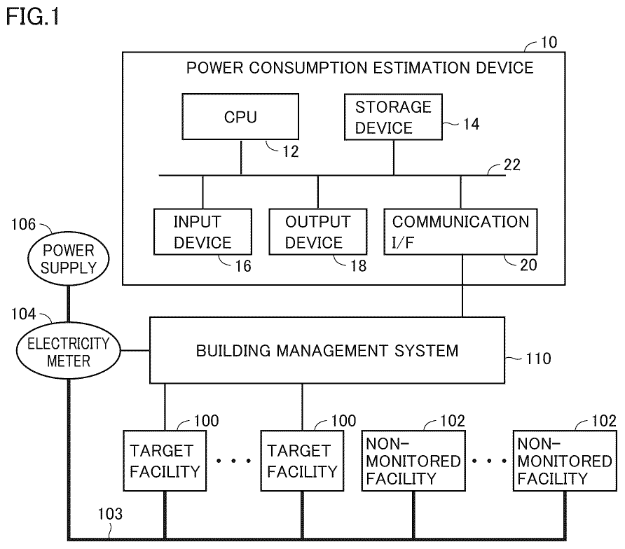

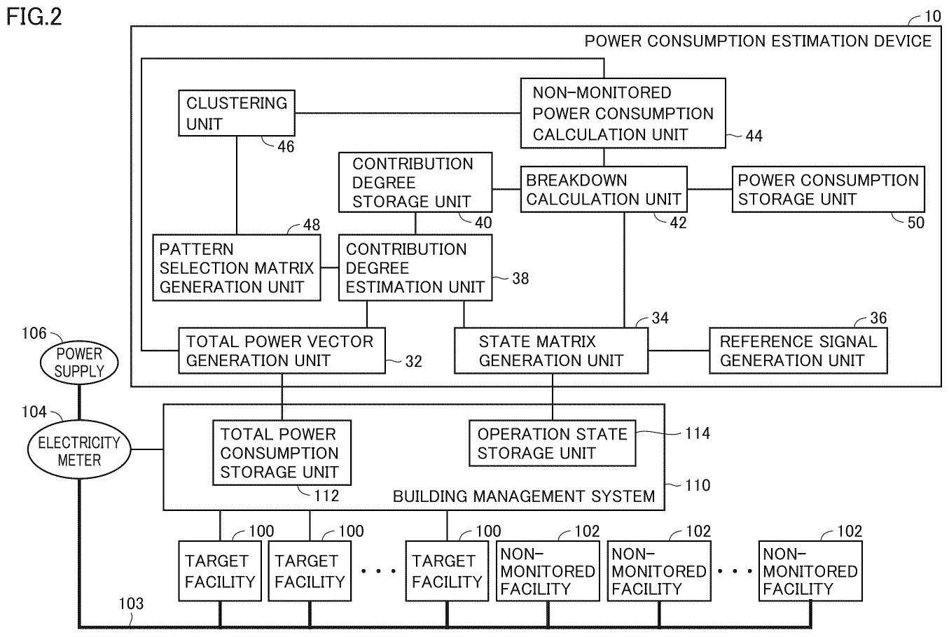

First, with reference to FIGS. 1 and 2, a schematic configuration of a power consumption estimation device according to a first embodiment will be described. FIG. 1 is a diagram illustrating a hardware configuration of power consumption estimation device 10 according to the first embodiment. FIG. 2 is a block diagram illustrating a functional configuration of power consumption estimation device 10 according to the first embodiment.

Power consumption estimation device 10 according to the first embodiment is a device that estimates the power consumption of each of at least one target facility 100 installed in a predetermined zone by means of regression analysis. The predetermined zone is, for example, an entire structure such as a building or a factory or an entire floor of the structure. Target facility 100 is a facility whose operation is controlled by a building management system 110, and is, for example, an air conditioning facility.

In general, a structure such as a building or a factory is provided with a power meter for measuring the power consumption of the entire structure or floor. The use of such an electricity meter makes it possible to grasp the total power consumption in the predetermined zone.

On the other hand, in a case where power is controlled for the purpose of energy saving, it is desirable to grasp not only the total power consumption but also the power consumption of each target facility 100. In order to accurately grasp the power consumption of each target facility 100, it is necessary to install an electricity meter for each target facility 100. Installing an electricity meter for each target facility 100, however, causes an increase in cost.

Therefore, power consumption estimation device 10 estimates the power consumption of each target facility 100 on the basis of the total power consumption throughout the predetermined zone and an operation state of each target facility 100. In the following description, an entire building is referred to as “predetermined zone”, and a plurality of air conditioning facilities installed throughout the building are each referred to as “target facility”.

As illustrated in FIG. 1, power consumption estimation device 10 includes one or more computers that are driven in accordance with a specific program. Power consumption estimation device 10 includes a central processing unit (CPU) 12, a storage device 14, an input device 16, an output device 18, and a communication I/F 20 as main components. The components are connected to each other over a data bus 22.

CPU 12 performs various calculations. Specifically, CPU 12 reads a power consumption estimation program stored in storage device 14, and performs various calculations necessary for estimating power consumption. Details of the processing performed by CPU 12 will be described later.

Storage device 14 stores various types of data including the program. Storage device 14 includes, for example, a combination of at least one of a read only memory (ROM) that stores data in a non-volatile manner, a random access memory (RAM) that stores data generated as a result of execution of the program or data input via input device 16 in a volatile manner, a hard disk drive (HDD) that stores data in a non-volatile manner, or the like. Storage device 14 stores the power consumption estimation program.

Input device 16 receives an operation instruction and data input from an operator. Input device 16 includes a combination of at least one of a keyboard, a mouse, a touch panel, a microphone, or the like, for example.

Output device 18 outputs various types of information to the operator. Output device 18 includes a combination of at least one of a display, a speaker, or the like, for example.

Communication I/F 20 is an interface for establishing communication with another device. For example, the total power consumption detected by building management system 110 and the operation state of target facility 100 are input to power consumption estimation device 10 via communication I/F 20. A result of the estimation performed by power consumption estimation device 10 can be transmitted to another device via communication I/F 20.

Note that although power consumption estimation device 10 is illustrated as one computer in FIG. 1, power consumption estimation device 10 may include a plurality of computers that can communicate with each other. Further, the connection between power consumption estimation device 10 and building management system 110 may be established in a wired or wireless manner. For example, the Internet can be used as the communication network connecting power consumption estimation device 10 and building management system 110. Alternatively, power consumption estimation device 10 may be a part of building management system 110.

In the example illustrated in FIG. 1, a plurality of the target facilities 100 and a plurality of non-monitored facilities 102 are installed in the building. The plurality of target facilities 100 and the plurality of non-monitored facilities 102 are connected to a power supply 106 via a power supply line 103, and receives power supplied from power supply 106 to operate. Note that both the number of target facilities 100 and the number of non-monitored facilities 102 may be one.

Target facility 100 is a facility whose power consumption is to be estimated, such as an air conditioning facility installed in the building. Target facility 100 is communicatively connected to building management system 110 and has its operation controlled by building management system 110.

Non-monitored facility 102 is a facility whose operation is not controlled by building management system 110 among facilities that consume power. Non-monitored facility 102 includes, for example, a light or an outlet installed in the building.

Power supply line 103 is provided with an electricity meter 104. Electricity meter 104 measures the total value of power supplied to the plurality of target facilities 100 and the plurality of non-monitored facilities 102, that is, the total power consumption throughout the building. Electricity meter 104 is communicatively connected to building management system 110, and transmits a measured value of the total power consumption to building management system 110.

As illustrated in FIG. 2, building management system 110 controls the operation of the plurality of target facilities 100 in accordance with a preset management program. Building management system 110 includes operation state storage unit 114 and total power consumption storage unit 112.

Operation state storage unit 114 stores time-series data of the operation state of each target facility 100. Specifically, building management system 110 periodically acquires the operation state of each target facility 100, and stores the acquired operation state and acquired date and time in operation state storage unit 114 with the operation state and the date and time associated with each other.

At this time, building management system 110 numerically represents the operation state. For example, “1” indicates that it is in operation, and “0” indicates that it is out of operation. Hereinafter, the numerical value indicating the operation state is also referred to as “operation parameter”. Note that the numerical value of the operation parameter is not limited to the binary number of “1” (in operation) and “0” (out of operation). As another form, the numerical value of the operation parameter may be set in multiple levels in accordance with an operation type, such as “1” indicating heating operation, “0.8” indicating cooling operation, “0.3” indicating ventilation operation, and “0” indicating out of operation. As still another form, the numerical value of the operation parameter may be set in accordance with a difference between an air-conditioning target temperature and the current room temperature, a rotation speed of a compressor, or the like. In any of the forms, operation state storage unit 114 stores time-series data of the numerical value (operation parameter) indicating the operation state of each of the plurality of target facilities 100.

Total power consumption storage unit 112 stores time-series data of the total value (total power consumption) of the power consumption throughout the building. Specifically, building management system 110 periodically acquires the total power consumption per unit time measured by electricity meter 104, and stores the acquired total power consumption and acquired date and time in total power consumption storage unit 112 with the total power consumption and the date and time associated with each other.

Note that it is desirable that the total power consumption coincide in sampling timing with the operation state of target facility 100 described above. Further, a sampling period is not particularly limited, but is desirably set greater than or equal to 30 seconds and less than or equal to 1 hour, and more desirably set greater than or equal to 1 minute and less than or equal to 10 minutes.

Further, in the example illustrated in FIG. 2, building management system 110 is configured to store the time-series data of the operation parameter and the time-series data of the total power consumption, but such pieces of data may be stored in storage device 14 provided in power consumption estimation device 10.

Power consumption estimation device 10 estimates the power consumption of each target facility 100 by performing multiple regression analysis with the total power consumption as an objective variable and the operation parameter and components of a reference signal to be described later as explanatory variables.

Specifically, power consumption estimation device 10 includes a total power vector generation unit 32, a state matrix generation unit 34, a reference signal generation unit 36, a contribution degree estimation unit 38, a contribution degree storage unit 40, a breakdown calculation unit 42, a non-monitored power consumption calculation unit 44, a clustering unit 46, a pattern selection matrix generation unit 48, and a power consumption storage unit 50.

Total power vector generation unit 32 generates a total power vector using the time-series data of the total power consumption stored in total power consumption storage unit 112. Assuming that the total power consumption at a certain sampling timing t is denoted as y(t), the total power vector is represented by [y(1), y(2), . . . , y(T)]. T denotes the number of samples constituting the total power vector. Total power vector generation unit 32 corresponds to an example of a “total power consumption acquisition unit” that acquires time-series data of the total power consumption y(t).

Here, total power consumption y(t) at certain sampling timing t is the sum of a total value (hereinafter, also referred to as “target power consumption”) X(t) of the power consumption of the plurality of target facilities 100 and a total value (hereinafter, also referred to as “non-monitored power consumption”) y^{u}(t) of the power consumption of the plurality of non-monitored facilities 102. That is, y(t)=X(t)+y^{u}(t).

Assuming that the power consumption of the i-th target facility 100 among the plurality of target facilities 100 depends on the operation state (operation parameter xi) of the i-th target facility 100, the power consumption of the i-th target facility 100 can be represented as (wᵢ·xᵢ). Here, wᵢ denotes a degree of contribution set for the i-th target facility 100. Accordingly, target power consumption X(t), which is the total value of the power consumption of the first to M-th target facilities 100, can be represented by the following expression (1).

[Math. 1]

X(t)=Σᵢ₌₁^{M}(wᵢ·xᵢ(t)) (1)

On the other hand, since the operation state of non-monitored facility 102 cannot be grasped, it is not possible to build a model like a model for target facility 100. Therefore, non-monitored power consumption y^{u}(t), which is the total value of the power consumption of the plurality of non-monitored facilities 102, is simulated using a plurality of reference signals φⱼ (i=0, 1, 2, . . . , N). Reference signal φⱼ corresponds to an example of a “first reference signal”.

Reference signal φⱼ is a signal that is represented by a predetermined basis function and is repeated every unit time (for example, every 24 hours). The type of the basis function is not particularly limited, but is desirably a mountain-shaped function or a rectangular function having a single peak. In the present embodiment, a Gaussian function shown in expression (2) is used as the basis function.

$$\begin{matrix}[ Math . 2 ] & \\ f ( t ) = exp \{ - \frac{{( t - μ )}^{2}}{2 \cdot {σ}^{2}} \} & ( 2 )\end{matrix}$$

The Gaussian function is a bell-shaped function, but the width of the mountain depends on σ, and the center of the mountain depends on μ. The j-th reference signal φⱼ is a signal that is represented by expression (2) and is repeated every 24 hours. Note that the plurality of reference signals is shifted in phase from each other by about ½ of the width of the mountain. Here, the width of the mountain is a period from when the value of the reference signal φⱼ becomes greater than 1% of the peak value to when the value becomes less than 1% of the peak value.

In the present embodiment, non-monitored power consumption y^{u}(t) is represented by the following expression (3) using the plurality of reference signals φ₀ to φ_{N}. Note that ^{u}wⱼ denotes a degree of contribution set for reference signal φⱼ. Further, φ₀=1 (constant). ^{u}w₀·φ₀ is a constant term, and denotes power constantly consumed without depending on time.

[Math. 3]

y^{u}(t)=Σⱼ₌₀^{N}(^{u}wⱼ·∅ⱼ(t)) (3)

State matrix generation unit 34 generates a state matrix on the basis of time-series data of an operation parameter xᵢ(t) stored in operation state storage unit 114 and a reference signal φⱼ(t) generated by reference signal generation unit 36. State matrix generation unit 34 corresponds to an example of an “operation state acquisition unit” that acquires the time-series data of operation parameter xᵢ(t). Reference signal generation unit 36 generates reference signal φⱼ(t) in response to a request from state matrix generation unit 34. Reference signal generation unit 36 corresponds to an example of a “first reference signal generation unit” that generates at least one first reference signal.

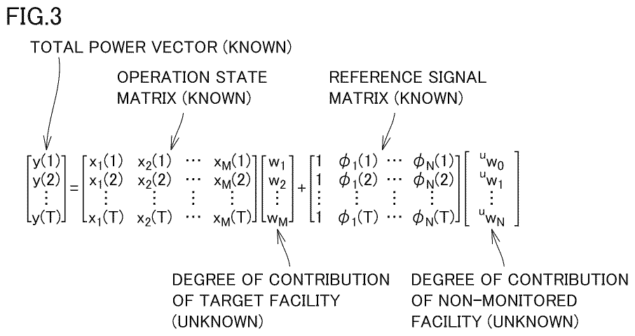

The generated total power vector and state matrix are input to contribution degree estimation unit 38. Contribution degree estimation unit 38 calculates degrees of contribution wᵢ and ^{u}wⱼ by substituting the total power vector and the state matrix into the following expression (4). Expression (4) is obtained as a result of modeling power consumption. Hereinafter, the regression model shown in expression (4) is also referred to as “first regression model”. The description of each term of expression (4) will be given in FIG. 3.

$$\begin{matrix}[ Math . 4 ] & \\ [ \begin{matrix}y ( 1 ) \\ y ( 2 ) \\ ⋮ \\ y ( T )\end{matrix} ] = [ \begin{matrix}{x}_{1} ( 1 ) & {x}_{2} ( 1 ) & … & {x}_{M} ( 1 ) \\ {x}_{1} ( 2 ) & {x}_{2} ( 2 ) & … & {x}_{M} ( 2 ) \\ ⋮ & ⋮ & ⋮ & ⋮ \\ {x}_{1} ( T ) & {x}_{2} ( T ) & … & {x}_{M} ( T )\end{matrix} ] [ \text{} \begin{matrix}{w}_{1} \\ {w}_{2} \\ ⋮ \\ {w}_{M}\end{matrix} ] + [ \begin{matrix}1 & {∅}_{1} ( 1 ) & … & {∅}_{N} ( 1 ) \\ 1 & {∅}_{1} ( 2 ) & … & {∅}_{N} ( 2 ) \\ ⋮ & ⋮ & ⋮ & ⋮ \\ 1 & {∅}_{1} ( T ) & … & {∅}_{N} ( T )\end{matrix} ] [ \begin{matrix}{u}^{} {w}_{0} \\ {u}^{} {w}_{1} \\ ⋮ \\ {u}^{} {w}_{N}\end{matrix} ] & ( 4 )\end{matrix}$$

The left side of expression (4) is the total power vector. The first term on the right side of expression (4) includes a state matrix based on the time-series data of operation parameter xᵢ(t). The second term on the right side of expression (4) includes a state matrix based on reference signal φⱼ(t). Hereinafter, the state matrix based on the time-series data of operation parameter xᵢ(t) is also referred to as “operation state matrix”, and the state matrix based on reference signal φⱼ(t) is also referred to as “reference signal matrix”.

In the first regression model of expression (4), total power consumption y(t), operation parameter xᵢ(t), and reference signal φⱼ(t) are known, and degrees of contribution wᵢ and ^{u}wⱼ are unknown. If degrees of contribution wᵢ and ^{u}wⱼ can be solved, power consumption wᵢ·xᵢ(t) of the i-th target facility 100 can be obtained.

Note that expression (4) can be solved if T>(M+N+1). Therefore, if total power consumption y(t) and operation parameter xᵢ(t) can be collected (M+N+1) times or more, degrees of contribution wᵢ and ^{u}wⱼ can be calculated. Note that a known multiple regression analysis technique is applicable to the calculation of degrees of contribution wᵢ and ^{u}wⱼ, so that no detailed description will be given of the calculation.

Degrees of contribution wᵢ and ^{u}wⱼ calculated by contribution degree estimation unit 38 are temporarily stored in contribution degree storage unit 40. Breakdown calculation unit 42 calculates the power consumption of the i-th target facility 100 by multiplying operation parameter xᵢ(t) of the i-th target facility 100 by degree of contribution wᵢ stored in contribution degree storage unit 40. Breakdown calculation unit 42 corresponds to an example of a “power consumption estimation unit”.

Breakdown calculation unit 42 further calculates non-monitored power consumption y^{u}(t), which is the total value of the power consumption of the plurality of non-monitored facilities 102, by substituting reference signal φⱼ(t) and degree of contribution ^{u}wⱼ into expression (3). Accordingly, a breakdown of total power consumption y(t) at sampling timing t is calculated.

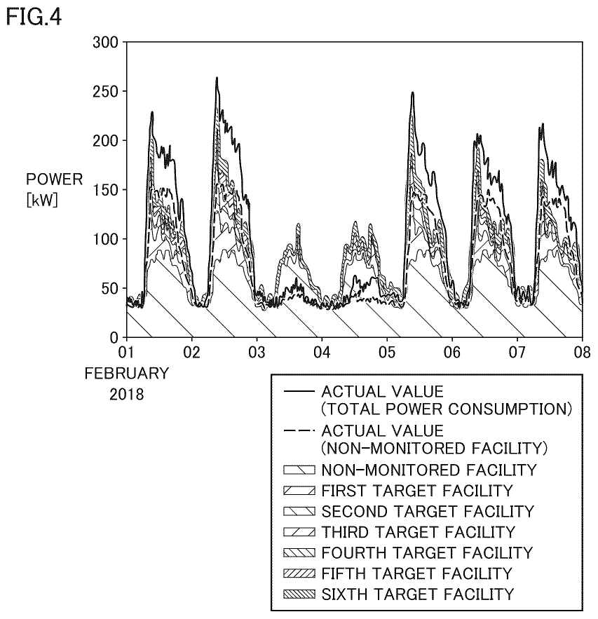

FIG. 4 is a graph showing changes over time in the power consumption of target facility 100 and the non-monitored power consumption estimated by means of multiple regression analysis using the first regression model shown in expression (4). In FIG. 4, the horizontal axis represents date and time during an estimation period, and the vertical axis represents power.

FIG. 4 shows waveforms of actual values of total power consumption y and non-monitored power consumption y^{u} of a certain building for one week (Feb. 1, 2018 to February 8). The solid line indicates a waveform of the actual value of total power consumption y throughout the building. The dashed line indicates a waveform of the actual value of non-monitored power consumption y^{u}.

FIG. 4 further shows waveforms of estimated values of power consumption and non-monitored power consumption y^{u} of the first to M-th target facilities 100. Note that, in the example shown in FIG. 4, M=6. FIG. 4 shows an area graph in which the estimated values of the power consumption of the first to M-th target facilities 100 are superimposed on the estimated value of non-monitored power consumption y^{u}.

That is, the height of the area graph is the sum of the estimated value of non-monitored power consumption y^{u} and the total value (that is, the estimated value of target power consumption X) of the estimated values of the power consumption of the first to M-th target facilities 100 at each sampling timing, and corresponds to the estimated value of total power consumption y. Such an area graph shows the estimated value of total power consumption y(t) and the breakdown of total power consumption y(t) at each sampling timing.

As is clear from FIG. 4, there is an error between the actual value (dashed line) of non-monitored power consumption y^{u} and the estimated value of non-monitored power consumption y^{u}. Specifically, the actual value of non-monitored power consumption y^{u} is greater than the estimated value for five days in a week, and the measured value of non-monitored power consumption y^{u} is less than the estimated value for the remaining two days. As a result, an error also occurs between the estimated value of total power consumption y, which is the sum of the estimated value of non-monitored power consumption y^{u} and the estimated value of target power consumption X, and the actual value of total power consumption y. As described above, when the error between the actual value of non-monitored power consumption y^{u} and the estimated value of non-monitored power consumption y^{u} increases, that is, when the accuracy of estimating non-monitored power consumption y^{u} decreases, a concern arises about a decrease in the accuracy of estimating the power consumption of each target facility 100.

Here, consider a factor that causes a decrease in the accuracy of estimating non-monitored power consumption y^{u}. The first regression model shown in expression (4) is obtained as a result of simulating non-monitored power consumption y^{u} using the plurality of reference signals φⱼ, and then modeling the power consumption using operation parameter xᵢ of target facility 100 and the plurality of reference signals φⱼ. In the multiple regression analysis using the first regression model, as shown in FIG. 4, the estimated value of non-monitored power consumption y^{u} has the same waveform pattern on any day of the week. That is, the first regression model of expression (4) is a model based on the assumption that the plurality of non-monitored facilities 102 repeat a single operation pattern every day.

On the other hand, as shown in FIG. 4, the actual value of non-monitored power consumption y^{u} has a waveform pattern that varies from day to day. That is, the operation patterns of the plurality of non-monitored facilities 102 vary from day to day. As a typical example, there is a case where the operation patterns of the plurality of non-monitored facilities 102 on weekdays are different from the operation patterns of the plurality of non-monitored facilities 102 on weekends.

Therefore, in order to increase the accuracy of estimating non-monitored power consumption y^{u}, it is necessary to divide the time-series data of total power consumption y(t) into a plurality of pieces of data in advance in accordance with the plurality of operation patterns of the plurality of non-monitored facilities 102, and perform multiple regression analysis on each piece of data. In order to perform such data division, it is necessary to obtain calendar information indicating weekdays and weekends in a target zone. In a case where the entire building is set as the target zone as in the present embodiment, it is, however, necessary to obtain calendar information from all properties in the building. Therefore, there is a concern about a lot of time and effort taken to obtain information and sort pieces of data.

Further, possible other methods of dividing the time-series data of total power consumption y(t) include a method of dividing, on the basis of the waveform of the time-series data of total power consumption y(t) per day measured by electricity meter 104, the time-series data into data corresponding to the operation pattern on weekdays and data corresponding to the operation pattern on weekends. However, the measured value of electricity meter 104 also includes the power consumption of target facility 100 such as an air conditioning facility, and in general, the power consumption is larger in power fluctuation than non-monitored power consumption y^{u}. Therefore, there is a problem that it is difficult to accurately divide the time-series data of total power consumption y(t) only with the waveform of the measured value of electricity meter 104.

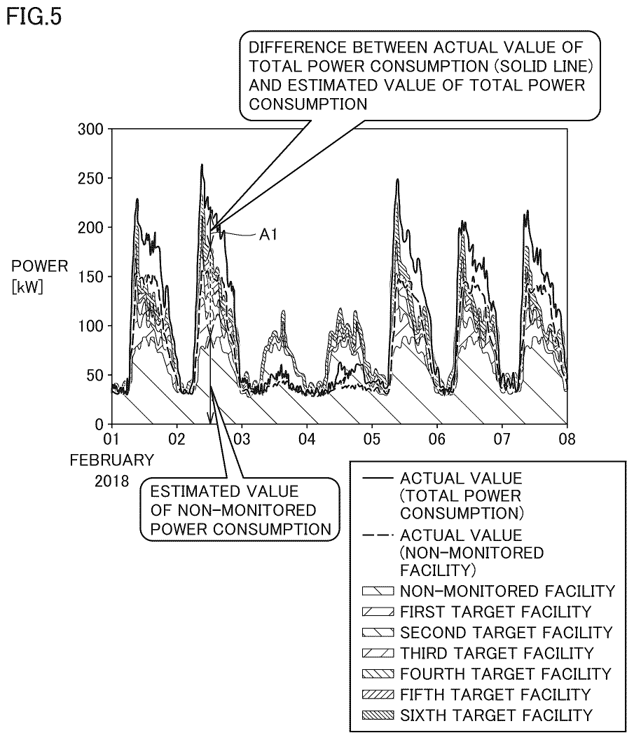

Therefore, in the present embodiment, non-monitored power consumption y^{u} is redefined using a difference between the estimated value of total power consumption y obtained from multiple regression analysis using the first regression model shown in expression (4) and the actual value of total power consumption y measured by electricity meter 104. First, with reference to FIG. 5, the redefinition of non-monitored power consumption y^{u} will be described. The following redefinition of non-monitored power consumption y^{u} is performed by non-monitored power consumption calculation unit 44.

FIG. 5 is a graph showing power consumption of target facility 100 and non-monitored power consumption estimated by means of multiple regression analysis using the first regression model shown in expression (4). The graph in FIG. 5 shows the same behavior as the graph in FIG. 4.

As described with reference to FIG. 4, the height of the area graph is the total value of the estimated value of non-monitored power consumption y^{u} and the estimated values of the power consumption of the first to M-th target facilities, and corresponds to the estimated value of total power consumption y. An arrow A1 in FIG. 4 indicates a difference between the actual value (solid line) of total power consumption y and the estimated value of total power consumption y. Hereinafter, a difference in a case where the actual value of total power consumption y is greater than the estimated value of total power consumption y is set as a positive value, and a difference in a case where the actual value of total power consumption y is less than the estimated value of total power consumption y is set as a negative value. The difference is a positive value for five days in a week, and the difference is a negative value for the remaining two days.

In the present embodiment, it is assumed that the difference (arrow A1) between the actual value of total power consumption y and the estimated value of total power consumption y is power derived from the power consumption of the plurality of non-monitored facilities 102. That is, it is assumed that the difference is derived from a difference between the operation pattern of non-monitored facility 102 assumed by the first regression model of expression (4) and the actual operation pattern of non-monitored facility 102. Non-monitored power consumption y^{u} is therefore redefined by adding the difference to the estimated value of non-monitored power consumption y^{u}.

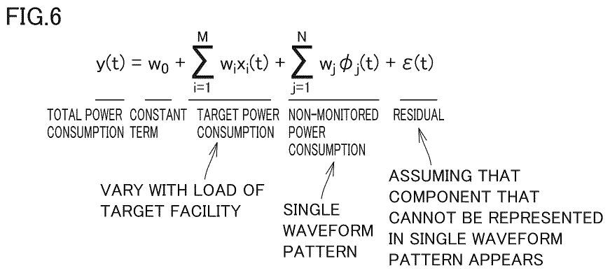

As described above, total power consumption y(t) at sampling timing t is the sum of target power consumption X(t) and non-monitored power consumption y^{u}(t). Total power consumption y(t) is represented by the following expression (5) using expressions (1) and (3). The description of each term of expression (5) will be given in FIG. 6.

[Math. 5]

y(t)=w₀+Σᵢ₌₁^{M}(wᵢ·xᵢ(t))+Σⱼ₌₁^{N}(^{u}wⱼ·∅ⱼ(t))+ε(t) (5)

The first term on the right side of expression (5) is a constant term, and denotes power constantly consumed without depending on time. The second term on the right side is target power consumption X(t) at sampling timing t. The third term on the right side is non-monitored power consumption y^{u}(t) at sampling timing t simulated using the plurality of reference signals φⱼ.

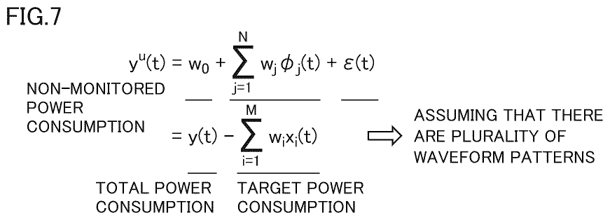

Here, c(t), which is the fourth term of expression (5), represents a residual between non-monitored power consumption y^{u}(t) simulated using the plurality of reference signals φⱼ and the actual value of non-monitored power consumption y^{u}(t). That is, it is assumed that residual ε(t) described above includes non-monitored power consumption y^{u}(t) that cannot be simulated using the plurality of reference signals φⱼ. As a result of transforming expression (5), non-monitored power consumption y^{u}(t) can be represented by the following expression (6). The description of each term of expression (6) will be given in FIG. 7.

$$\begin{matrix}[ Math . 6 ] & \\ {y}^{u} ( t ) = {w}_{0} + {\sum }_{j = 1}^{N} {(}^{u} {w}_{j} \cdot {∅}_{j} ( t ) ) + ε ( t ) = y ( t ) - {\sum }_{i = 1}^{M} ( {w}_{i} \cdot {x}_{i} ( t ) ) & ( 6 )\end{matrix}$$

When breakdown calculation unit 42 calculates a tentative breakdown of total power consumption y(t) at sampling timing t, non-monitored power consumption calculation unit 44 subtracts the estimated value of target power consumption X(t) from total power consumption y(t) using expression (6) to obtain non-monitored power consumption y^{u}(t). Accordingly, non-monitored power consumption calculation unit 44 redefines non-monitored power consumption y^{u}(t) so as to cause non-monitored power consumption y^{u}(t) to include residual ε(t).

It is assumed that the time-series data of redefined non-monitored power consumption y^{u}(t) has a plurality of waveform patterns corresponding to the plurality of operation patterns of the plurality of non-monitored facilities 102. Clustering unit 46 classifies (performs clustering on) the time-series data of redefined non-monitored power consumption y^{u}(t) into similar waveform patterns.

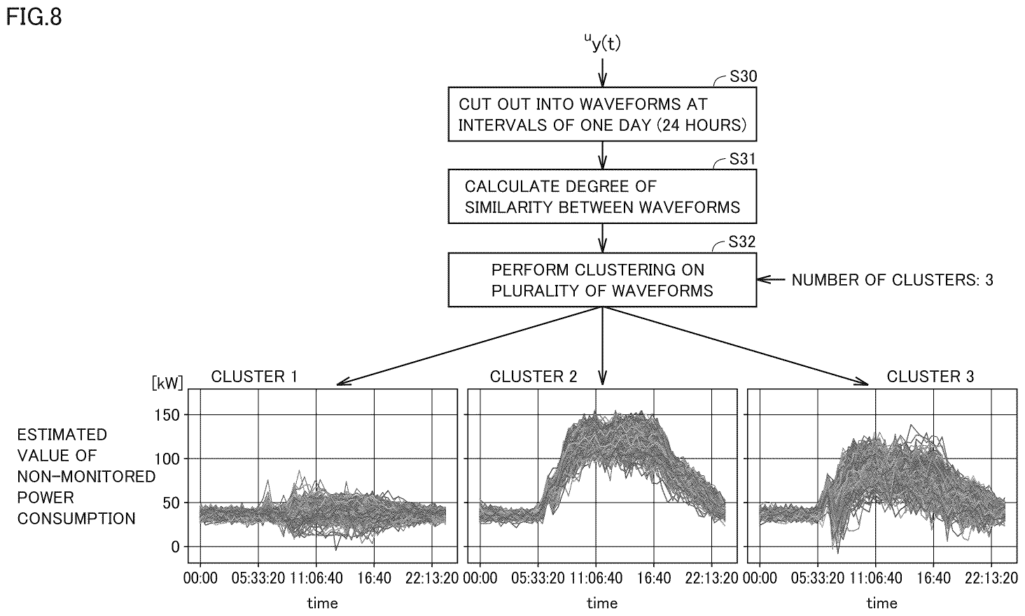

FIG. 8 is a diagram for describing clustering processing performed by clustering unit 46. As illustrated in FIG. 8, clustering unit 46 first cuts out the time-series data of redefined non-monitored power consumption y^{u}(t) into waveforms at predetermined time intervals (step S30). The predetermined time can be set on the basis of the period of the operation pattern of the plurality of non-monitored facilities 102. In the example illustrated in FIG. 8, the predetermined period is set to one day (24 hours).

Next, clustering unit 46 calculates a degree of similarity between the plurality of waveforms cut out in step S30 (step S31). A known method such as dynamic time warping (DTW) can be used to calculate the degree of similarity between the waveforms.

Next, clustering unit 46 performs clustering for classifying the plurality of waveforms into a predetermined number of clusters using the calculated degree of similarity (step S33). That is, clustering unit 46 classifies the plurality of waveforms into a predetermined number of groups. As described above, similar waveforms are grouped into one cluster. In the example illustrated in FIG. 8, hierarchical clustering is applied. For the clustering, instead of hierarchical clustering, non-hierarchical clustering or any other method may be used.

In the example illustrated in FIG. 8, the plurality of waveforms is classified into three clusters (clusters 1 to 3). Waveforms of non-monitored power consumption y^{u}(t) per day fall into each of clusters 1 to 3. The use of hierarchical clustering allows any number of clusters to be obtained. It is, however, preferable to set the number of clusters on the basis of the number of operation patterns of non-monitored facility 102. For example, in a case where it is assumed that there are at least two operation patterns on weekdays and at least one operation pattern on weekends, the number of clusters is preferably set greater than or equal to three.

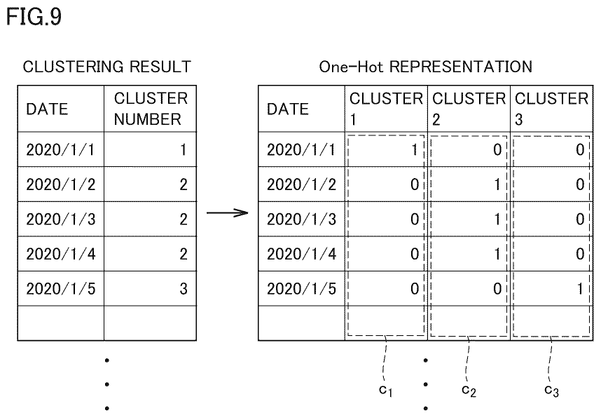

When clustering is performed on the time-series data of non-monitored power consumption y^{u}(t), a clustering result in which the date and the cluster number are associated with each other is obtained for each waveform. FIG. 9 is a diagram illustrating an example of the clustering result. In a clustering result illustrated on the left side of the drawing, the date indicates a date when total power consumption y(t) corresponding to non-monitored power consumption y^{u}(t) is measured for each waveform. The cluster number indicates a cluster number of any one of three clusters 1 to 3 described above into which corresponding waveforms fall.

Pattern selection matrix generation unit 48 converts the clustering result into One-Hot representation. The One-Hot representation is vector representation in which only a certain element is “1” and the other elements are “0”. As illustrated in FIG. 9, the clustering result of each date is represented by a vector having three elements. The three elements of the vector correspond to three clusters 1 to 3 on a one-to-one basis. For each date, an element corresponding to a cluster into which corresponding waveforms fall is set to “1” (selected state), and the other two elements are set to “0” (unselected state).

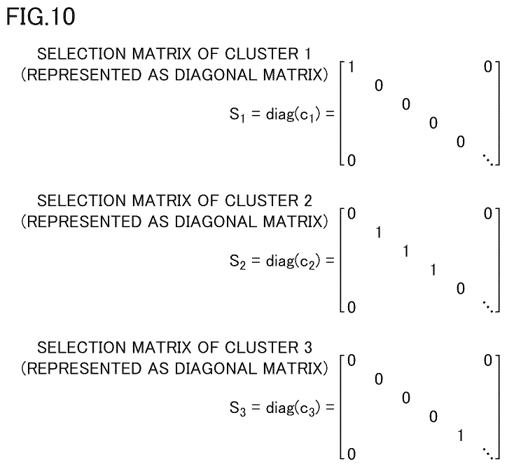

Pattern selection matrix generation unit 48 generates a pattern selection matrix by converting the One-Hot encoded clustering result into a diagonal matrix. The pattern selection matrix has the One-Hot encoded clustering result as a diagonal element. FIG. 10 is a diagram illustrating a pattern selection matrix generated from the clustering result illustrated in FIG. 9.

As illustrated in FIG. 10, the pattern selection matrix includes a selection matrix S₁ corresponding to cluster 1, a selection matrix S₂ corresponding to cluster 2, and a selection matrix S₃ corresponding to cluster 3.

Selection matrix S₁ is represented by S₁=diag(C₁). C₁ denotes column components (1, 0, 0, 0, 0, . . . ) corresponding to cluster 1 in the One-Hot representation illustrated in FIG. 9. diag(C₁) denotes a diagonal matrix with column components C₁ as diagonal elements.

Selection matrix S₂ is represented by S₂=diag(C₂). C₂ denotes column components (0, 1, 1, 1, 0, . . . ) corresponding to cluster 2 in the One-Hot representation illustrated in FIG. 9. diag(C₂) denotes a diagonal matrix with column components C₂ as diagonal elements.

Selection matrix S₃ is represented by S₃=diag(C₃). C₃ denotes column components (0, 0, 0, 0, 1, . . . ) corresponding to cluster 3 in the One-Hot representation illustrated in FIG. 9. diag(C₃) denotes a diagonal matrix with column components C₃ as diagonal elements.

Generated pattern selection matrices S₁, S₂, and S₃ are input to contribution degree estimation unit 38. Contribution degree estimation unit 38 models power consumption again using pattern selection matrices S₁, S₂, and S₃. The following expression (7) is the regenerated regression model. Hereinafter, the regression model shown in expression (7) is also referred to as “second regression model”.

$$\begin{matrix}[ Math . 7 ] & \\ [ \begin{matrix}y ( 1 ) \\ y ( 2 ) \\ ⋮ \\ y ( T )\end{matrix} ] = [ \text{} \begin{matrix}{x}_{1} ( 1 ) & {x}_{2} ( 1 ) & … & {x}_{M} ( 1 ) \\ {x}_{1} ( 2 ) & {x}_{2} ( 2 ) & … & {x}_{M} ( 2 ) \\ ⋮ & ⋮ & ⋮ & ⋮ \\ {x}_{1} ( T ) & {x}_{2} ( T ) & … & {x}_{M} ( T )\end{matrix} ] [ \text{} \begin{matrix}{w}_{1} \\ {w}_{2} \\ ⋮ \\ {w}_{M}\end{matrix} ] + [ \begin{matrix}1 & & & 0 \\ & 0 & & \\ & & 0 & \\ 0 & & & ⋱\end{matrix} ] [ \begin{matrix}1 & {∅}_{1} ( 1 ) & … & {∅}_{N} ( 1 ) \\ 1 & {∅}_{1} ( 2 ) & … & {∅}_{N} ( 2 ) \\ ⋮ & ⋮ & ⋮ & ⋮ \\ 1 & {∅}_{1} ( T ) & … & {( ∅ )}_{N} ( T )\end{matrix} ] [ \begin{matrix}{c 1}^{} {w}_{0} \\ {c 1}^{} {w}_{1} \\ ⋮ \\ {c 1}^{} {w}_{N}\end{matrix} ] + [ \begin{matrix}0 & & & 0 \\ & 1 & & \\ & & 1 & \\ 0 & & & ⋱\end{matrix} ] [ \begin{matrix}1 & {∅}_{1} ( 1 ) & … & {∅}_{N} ( 1 ) \\ 1 & {∅}_{1} ( 2 ) & … & {∅}_{N} ( 2 ) \\ ⋮ & ⋮ & ⋮ & ⋮ \\ 1 & {∅}_{1} ( T ) & … & {( ∅ )}_{N} ( T )\end{matrix} ] [ \begin{matrix}{c 2}^{} {w}_{0} \\ {c 2}^{} {w}_{1} \\ ⋮ \\ {c 2}^{} {w}_{N}\end{matrix} ] + [ \begin{matrix}0 & & & 0 \\ & 0 & & \\ & & 0 & \\ 0 & & & ⋱\end{matrix} ] [ \begin{matrix}1 & {∅}_{1} ( 1 ) & … & {∅}_{N} ( 1 ) \\ 1 & {∅}_{1} ( 2 ) & … & {∅}_{N} ( 2 ) \\ ⋮ & ⋮ & ⋮ & ⋮ \\ 1 & {∅}_{1} ( T ) & … & {( ∅ )}_{N} ( T )\end{matrix} ] [ \begin{matrix}{c 3}^{} {w}_{0} \\ {c 3}^{} {w}_{1} \\ ⋮ \\ {c 3}^{} {w}_{N}\end{matrix} ] & ( 7 )\end{matrix}$$

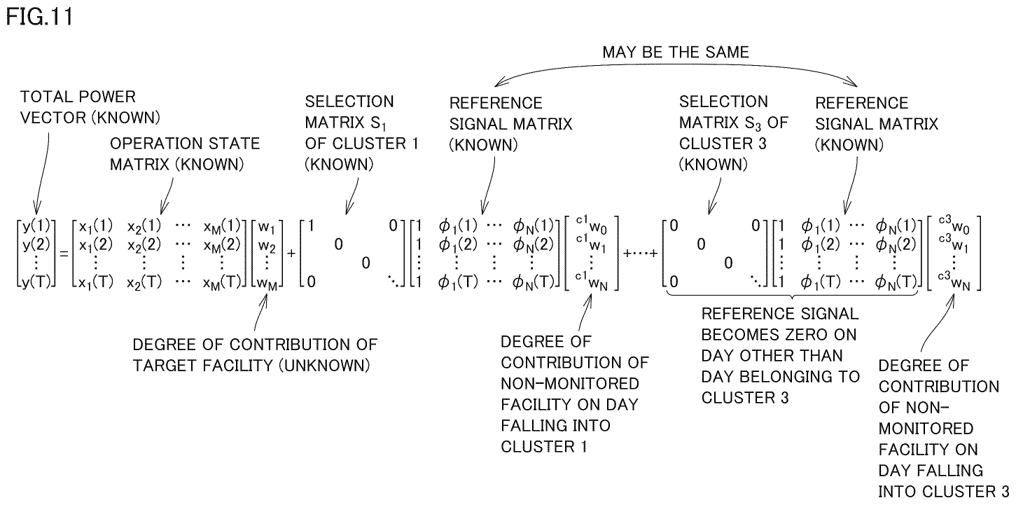

The description of each term of expression (7) will be given in FIG. 11. The left side of expression (7) is a total power vector generated from the time-series data of total power consumption y(t) stored in total power consumption storage unit 112.

The first term on the right side of expression (7) is obtained by multiplying the state matrix (operation state matrix) generated on the basis of the time-series data of operation parameter xᵢ(t) stored in operation state storage unit 114 by degree of contribution wᵢ of target facility 100, and the first term represents total power consumption X(t) that is the total value of the power consumption of target facility 100.

The second term on the right side of expression (7) is obtained by multiplying selection matrix S₁ of cluster 1 by the state matrix (reference signal matrix) generated on the basis of reference signal φⱼ (first reference signal) generated by reference signal generation unit 36 and a degree of contribution ^{c1}wⱼ of non-monitored facility 102 on the day that falls into cluster 1. The second term represents non-monitored power consumption y^{u}(t) that falls into cluster 1.

The third term on the right side of expression (7) is obtained by multiplying selection matrix 52 of cluster 2 by the reference signal matrix and a degree of contribution ^{c2}wⱼ of non-monitored facility 102 on the day that falls into cluster 2. The third term represents non-monitored power consumption y^{u}(t) that falls into cluster 2.

The fourth term on the right side of expression (7) is obtained by multiplying selection matrix S₃ of cluster 3 by the reference signal matrix and a degree of contribution ^{c3}wⱼ of non-monitored facility 102 on the day that falls into cluster 3. The fourth term represents non-monitored power consumption y^{u}(t) that falls into cluster 3.

As described above, the second regression model shown in expression (7) is different from the first regression model shown in expression (4) in that non-monitored power consumption y^{u}(t) is represented by non-monitored power consumption y^{u}(t) classified into the plurality of clusters. As described above, the number of clusters is set on the basis of the number of operation patterns of the plurality of non-monitored facilities 102. That is, in the regression model shown in expression (7), non-monitored power consumption y^{u}(t) is represented with non-monitored power consumption y^{u}(t) classified for each operation pattern of non-monitored facility 102.

In the second regression model shown in expression (7), total power consumption y(t), operation parameter xᵢ(t) of target facility 100, reference signal φⱼ, and selection matrices S₁, S₂, and S₃ are known. Degrees of contribution wᵢ, ^{c1}wⱼ, ^{c2}wⱼ, and ^{c3}wⱼ are unknown. Contribution degree estimation unit 38 calculates degrees of contribution wᵢ, ^{c1}wⱼ, ^{c2}wⱼ, and ^{c3}wⱼ by substituting the total power vector, the operation state matrix, and the reference signal matrix into expression (7). A known multiple regression analysis technique can be used for this calculation. Degree of contributions wᵢ and ^{u}wⱼ calculated using the first regression model each correspond to “tentative degree of contribution” that is tentatively estimated. Degree of contributions wᵢ, ^{c1}wⱼ, ^{c2}wⱼ, and ^{c3}wⱼ calculated using the second regression model each correspond to “determined degree of contribution” that is a determined degree of contribution.

Degrees of contribution wᵢ, ^{c1}wⱼ, ^{c2}wⱼ, and ^{c3}wⱼ calculated by contribution degree estimation unit 38 are stored in contribution degree storage unit 40. Accordingly, degree of contribution wᵢ is determined, and tentative degree of contribution ^{u}wⱼ is replaced with determined degrees of contribution ^{c1}wⱼ, ^{c2}wⱼ, and ^{c3}wⱼ .

Breakdown calculation unit 42 calculates the power consumption of the i-th target facility 100 by multiplying operation parameter xᵢ of target facility 100 by degree of contribution wᵢ stored in contribution degree storage unit 40. Further, breakdown calculation unit 42 calculates non-monitored power consumption y^{u}(t) by substituting reference signal φⱼ and degrees of contribution ^{c1}wⱼ, ^{c2}wⱼ, and ^{c3}wⱼ into the following expression (8).

$$\begin{matrix}[ Math . 8 ] & \\ {y}^{u} ( t ) = {\sum }_{j = 1}^{N} ( {S}_{1} \cdot {}^{c 1} {w}_{j} \cdot {∅}_{j} ( t ) ) + {\sum }_{j = 1}^{N} ( {S}_{2} \cdot {}^{c 2} {w}_{j} \cdot {∅}_{j} ( t ) ) + {\sum }_{j = 1}^{N} ( {S}_{3} \cdot {}^{c 3} {w}_{j} \cdot {∅}_{j} ( t ) ) & ( 8 )\end{matrix}$$

As shown in expression (8), non-monitored power consumption y^{u}(t) is represented by using elements S₁, S₂, and S₃ that each become “1” (selected state) for a corresponding cluster and become “0” (unselected state) for the other clusters, the plurality of reference signals φⱼ(t), and degree of contribution ^{c}wⱼ of non-monitored facility 102 for the corresponding cluster. Hereinafter, the product of each of elements S₁, S₂, and S₃ and the plurality of reference signals φⱼ is also referred to as “second reference signal”. Each of the plurality of second reference signals is generated for a corresponding one of the plurality of clusters. Pattern selection matrix generation unit 48 corresponds to an example of a “second reference signal generation unit” for generating the plurality of second reference signals.

Accordingly, the breakdown of total power consumption y(t) at sampling timing t is calculated. The calculated breakdown (power consumption of each target facility 100 and non-monitored power consumption y^{u}(t)) is stored in power consumption storage unit 50 with the breakdown associated with the time.

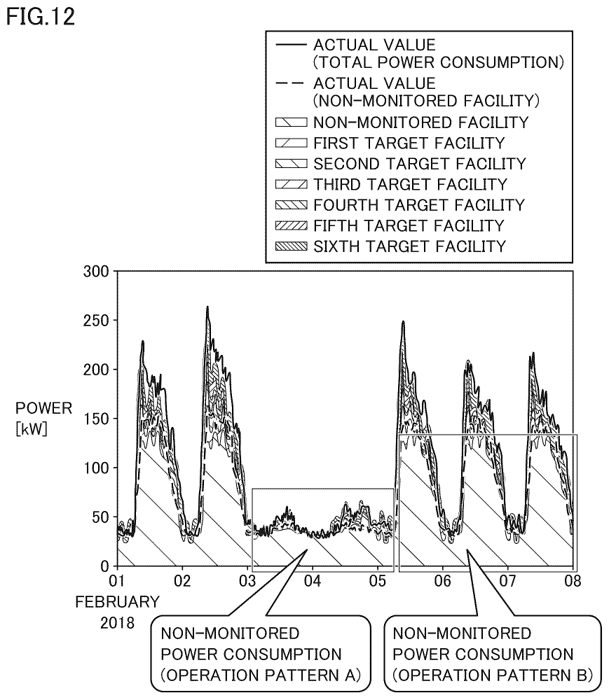

FIG. 12 is a graph showing the power consumption of target facility 100 and non-monitored power consumption y^{u} estimated by means of multiple regression analysis using the second regression model shown in expression (7). In FIG. 12, both a graph (solid line) showing the measured value of total power consumption y and a graph (dashed line) showing the measured value of non-monitored power consumption y^{u} show the same behavior as the graph in FIG. 4.

FIG. 12 shows waveforms of the estimated values of the power consumption of the first to M-th target facilities 100 and the estimated value of non-monitored power consumption y^{u} calculated from multiple regression analysis using the second regression model shown in expression (7). As in FIG. 4, FIG. 12 shows an area graph in which the estimated values of the power consumption of the first to M-th target facilities 100 are superimposed on the estimated value of non-monitored power consumption y^{u}. The area graph shows the estimated value of total power consumption y(t) at each sampling timing t and the breakdown of total power consumption y(t).

In FIG. 12, as compared with FIG. 5, an error between the actual value of non-monitored power consumption y^{u} and the estimated value of non-monitored power consumption y^{u} is smaller on any day of one week. Specifically, in FIG. 12, the actual value of non-monitored power consumption y^{u} for one week has waveform patterns including waveform patterns for five days and waveform patterns for the remaining two days different from the waveform patterns for five days. This is because the operation patterns of the plurality of non-monitored facilities 102 are different between the five days and the two days. In FIG. 12, the operation pattern for the two days is referred to as operation pattern A, and the operation pattern for the five days is referred to as operation pattern B.

As described above, in the second regression model shown in expression (7), non-monitored power consumption y^{u}(t) is represented with non-monitored power consumption y^{u}(t) classified for each operation pattern of the plurality of non-monitored facilities 102. It is therefore possible to accurately estimate non-monitored power consumption y^{u} for each of operation patterns A and B. Since non-monitored power consumption y^{u} can be accurately estimated as described above, the accuracy of estimating the power consumption of target facility 100 also increases. This is also apparent from the fact that, in FIG. 12, the error between the estimated value of total power consumption y, which is the sum of the estimated value of non-monitored power consumption y^{u} and the total value of the estimated values of the power consumption of the first to M-th target facilities 100, and the actual value of total power consumption y is small.

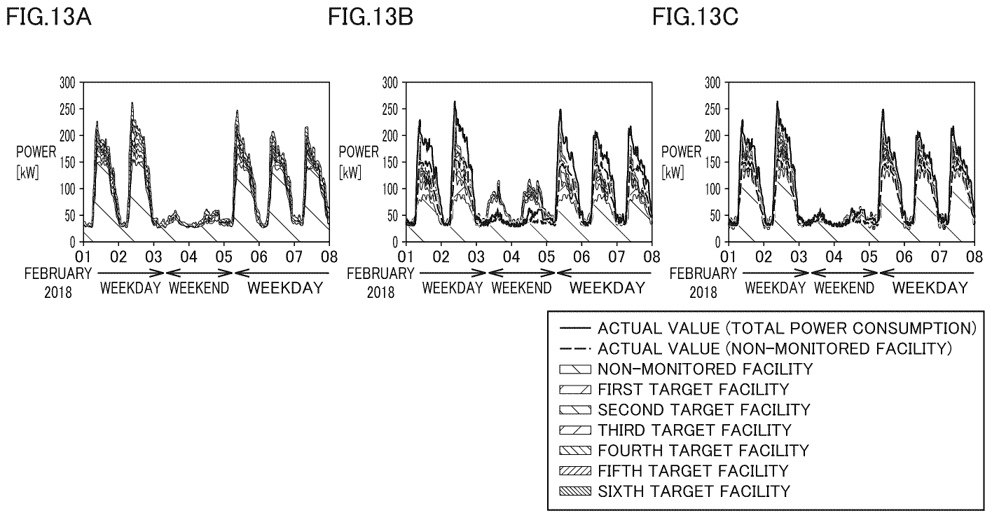

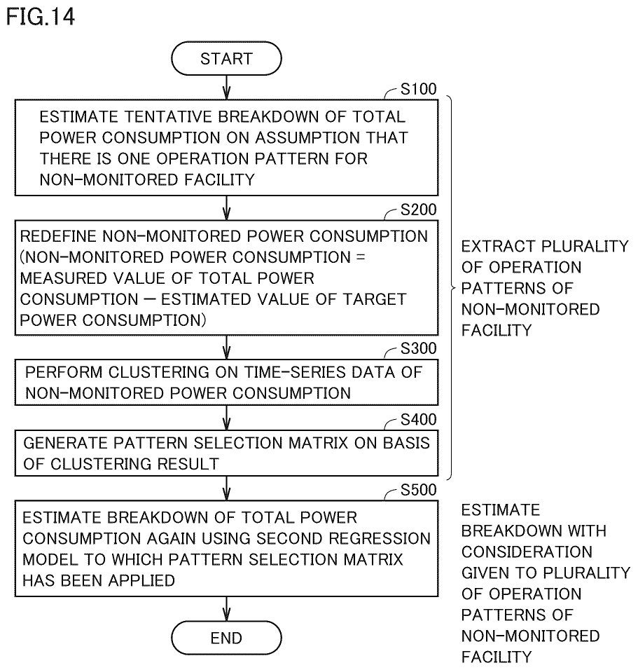

FIGS. 13A, 13B and 14C are diagrams showing a result of comparison between the first embodiment and a conventional technique regarding the accuracy of estimating power consumption. FIG. 13A is ground truth data on the breakdown of the total power consumption for one week (Feb. 1, 2018 to February 8) of the certain building. FIG. 13A shows an area graph based on the actual value of the power consumption of the first to M-th target facilities 100 and the actual value of the non-monitored power consumption. Five days in the week are weekdays, and the remaining two days are a weekend. For both the power consumption of each target facility 100 and the non-monitored power consumption, the actual value on the weekdays is greater than the actual value on the weekend. The total power consumption on the weekdays is therefore greater than the total power consumption on the weekend. Note that only the total power consumption can be actually measured by the power consumption estimation device.

FIG. 13B is a result of estimating the breakdown of the total power consumption according to the conventional technique. The estimation result shown in FIG. 13B is obtained by means of multiple regression analysis using the first regression model shown in expression (4). That is, the estimation result is obtained by using the regression model based on the assumption that the plurality of non-monitored facilities 102 repeat a single operation pattern every day.

FIG. 13C shows a result of estimating the breakdown of the total power consumption according to the first embodiment. FIG. 13C is obtained by means of multiple regression analysis using the second regression model shown in expression (7). That is, the estimation result is obtained by using the regression model based on the assumption that the plurality of non-monitored facilities 102 have a plurality of operation patterns.

A comparison between FIG. 13A and FIG. 13B shows that the power consumption on the weekdays is estimated to be less than the ground truth data, while the power consumption on the weekend is estimated to be greater than the ground truth data in the conventional technique. Therefore, the estimation accuracy deteriorates.

On the other hand, as shown in FIG. 13C, an error between the power consumption and the ground truth data is smaller on both the weekdays and the weekend in the first embodiment. The increase in the accuracy of estimating the non-monitored power consumption also yields an increase in the accuracy of estimating the power consumption of target facility 100.

### <Operation of Power Consumption Estimation Device>

Next, a flow of power consumption estimation processing performed by power consumption estimation device 10 according to the first embodiment will be described.

FIG. 14 is a flowchart illustrating an example of the flow of the power consumption estimation processing performed by power consumption estimation device 10 according to the first embodiment.

As illustrated in FIG. 14, power consumption estimation device 10 first estimates a tentative breakdown of the power consumption (step S100) by performing multiple regression analysis using the first regression model shown in expression (4). The first regression model is a regression model based on the assumption that there is one operation pattern for the plurality of non-monitored facilities 102. That is, in step S100, after simulating non-monitored power consumption y^{u} using the plurality of reference signals Φⱼ (first reference signals), tentative power consumption of each target facility 100 is estimated by means of multiple regression analysis performed with the time-series data of total power consumption y as an objective variable and the time-series data of operation parameters xᵢ of the plurality of target facilities 100 and the plurality of reference signals Φⱼ as explanatory variables.

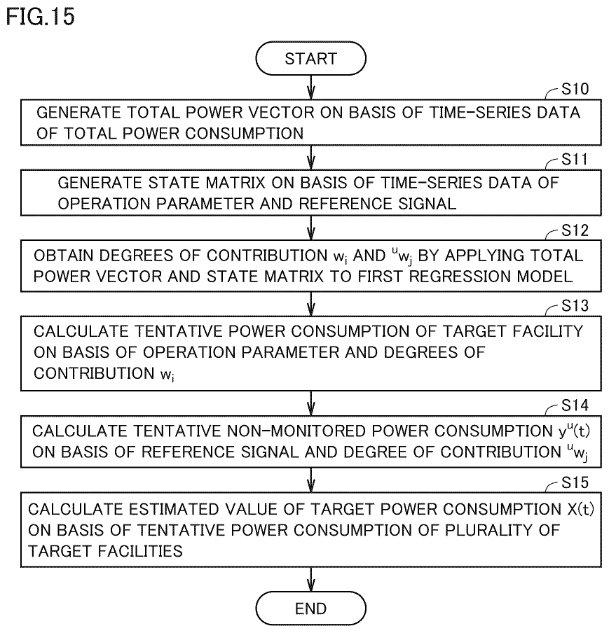

FIG. 15 is a flowchart illustrating a detailed process flow of step S100 in FIG. 14.

As illustrated in FIG. 15, power consumption estimation device 10 first generates a total power vector on the basis of the time-series data of total power consumption y(t) (step S10). Further, power consumption estimation device 10 generates an operation state matrix on the basis of the time-series data of operation parameters xᵢ(t) of the plurality of target facilities 100, and generates a reference signal matrix on the basis of reference signal Φⱼ(t) (step S11).

Power consumption estimation device 10 applies the generated total power vector and state matrices (operation state matrix and reference signal matrix) to the first regression model shown in expression (4). Power consumption estimation device 10 calculates degrees of contribution wᵢ and ^{u}wⱼ (tentative degrees of contribution) by performing multiple regression analysis using the first regression model shown in expression (4) (step S12).

Next, power consumption estimation device 10 estimates the tentative breakdown of the total power consumption using calculated degree of contributions wᵢ and ^{u}wⱼ. Specifically, power consumption estimation device 10 calculates tentative power consumption of the i-th target facility 100 by multiplying the time-series data of operation parameter xᵢ(t) of the i-th target facility 100 by degree of contribution wᵢ (step S13). Further, power consumption estimation device 10 calculates tentative non-monitored power consumption y^{u}(t) by substituting reference signal Φⱼ(t) and degree of contribution ^{u}wⱼ into expression (3) (step S14).

When the tentative power consumption of the first to M-th target facilities 100 and tentative non-monitored power consumption y^{u}(t) are calculated, power consumption estimation device 10 calculates target power consumption X(t), which is the total value of the power consumption of the first to M-th target facilities 100, according to expression (1) (step S15). Calculated target power consumption X(t) corresponds to a value of target power consumption X(t) estimated by means of multiple regression analysis using the first regression model shown in expression (4).

Returning to FIG. 14, power consumption estimation device 10 next redefines non-monitored power consumption y^{u} on the basis of the result of estimating the tentative breakdown of the power consumption obtained in S100 (step S200). In step S200, power consumption estimation device 10 calculates non-monitored power consumption y^{u}(t) by subtracting the estimated value of target power consumption X(t) obtained by the estimation process in S100 from the measured value of total power consumption y(t) according to expression (6).

Next, power consumption estimation device 10 classifies (performs clustering on) the time-series data of redefined non-monitored power consumption y^{u}(t) into similar waveform patterns (step S300). In step S300, according to the process flow illustrated in FIG. 8, power consumption estimation device 10 divides the time-series data of non-monitored power consumption y^{u}(t) into a plurality of waveforms at predetermined time intervals (24 hours). Then, power consumption estimation device 10 classifies the plurality of waveforms into a predetermined number of clusters on the basis of a degree of similarity between the waveforms.

Power consumption estimation device 10 generates a pattern selection matrix on the basis of the clustering result obtained in S300 (step S400). In S400, as illustrated in FIGS. 9 and 10, power consumption estimation device 10 generates a predetermined number of pattern selection matrices corresponding to the number of clusters by converting the One-Hot encoded clustering result into a diagonal matrix. Power consumption estimation device 10 generates a plurality of second reference signals corresponding, on a one-to-one basis, to the plurality of clusters on the basis of the generated pattern selection matrix and the plurality of reference signals Φⱼ.

Power consumption estimation device 10 generates the second regression model shown in expression (7) using the generated pattern selection matrix, a total power vector, and the state matrices (operation state matrix and reference signal matrix). The second regression model is a regression model based on the assumption that there is a plurality of operation patterns for the plurality of non-monitored facilities 102. Power consumption estimation device 10 estimates the power consumption of each target facility 100 by performing multiple regression analysis again using the generated second regression model (step S500).

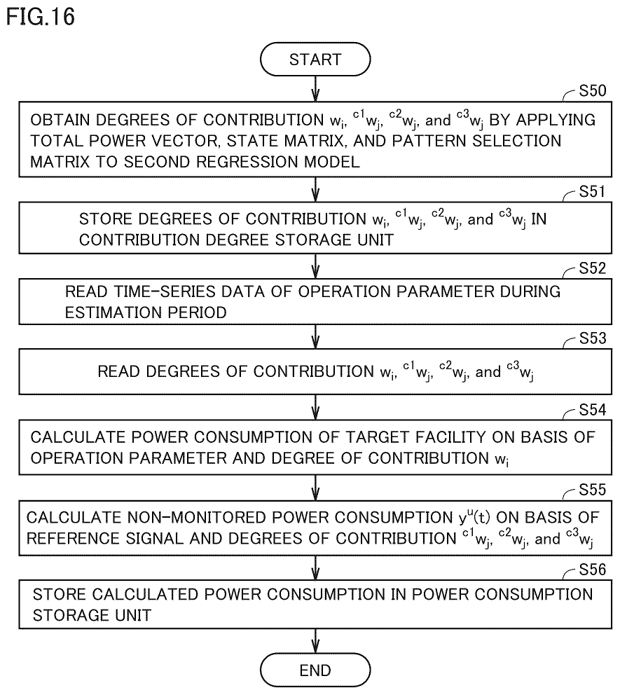

FIG. 16 is a flowchart illustrating a detailed process flow of step S500 in FIG. 15.

As illustrated in FIG. 16, power consumption estimation device 10 applies the total power vector and the state matrices (operation state matrix and reference signal matrix) generated in S100 and the pattern selection matrix generated in S400 to the second regression model shown in expression (7). Power consumption estimation device 10 calculates degrees of contribution wᵢ, ^{c1}wⱼ, ^{c2}wⱼ, and ^{c3}wⱼ (determined degrees of contribution) by performing multiple regression analysis using the second regression model shown in expression (7) (step S50).

Power consumption estimation device 10 stores calculated degrees of contribution wᵢ, ^{c1}wⱼ, ^{c2}wⱼ, and ^{c3}wⱼ in contribution degree storage unit 40 (step S51).

Power consumption estimation device 10 estimates the breakdown of the total power consumption using degrees of contribution wᵢ, ^{c1}wⱼ, ^{c2}wⱼ, and ^{c3}wⱼ stored in contribution degree storage unit 40. Specifically, power consumption estimation device 10 reads the time-series data of operation parameters xᵢ(t) of the plurality of target facilities 100 acquired during the period in which the breakdown is to be estimated (step S52). Further, power consumption estimation device 10 reads degrees of contribution wᵢ, ^{c1}wⱼ, ^{c2}wⱼ, and ^{c3}wⱼ stored in contribution degree storage unit 40 (step S53).

Next, power consumption estimation device 10 calculates the power consumption of the i-th target facility 100 by multiplying operation parameter xᵢ(t) of the i-th target facility 100 by degree of contribution wᵢ (step S54). Further, power consumption estimation device 10 calculates non-monitored power consumption y^{u}(t) by substituting reference signal φⱼ(t) and degrees of contribution wᵢ, ^{c1}wⱼ, ^{c2}wⱼ, and ^{c3}wⱼ into expression (8) (step S55). Power consumption estimation device 10 stores the calculated power consumption of the first to M-th target facilities 100 and non-monitored power consumption y^{u}(t) in power consumption storage unit 50 (step S56).

As described above, the power consumption estimation device according to the first embodiment can accurately estimate the non-monitored power consumption that varies in a manner that depends on the plurality of operation patterns of the plurality of non-monitored facilities 102. Then, since the non-monitored power consumption can be accurately estimated as described above, the power consumption of each target facility can be accurately estimated.

Furthermore, the power consumption estimation device according to the first embodiment eliminates the need of dividing the time-series data of the total power consumption into a plurality of pieces of data in accordance with the plurality of operation patterns of the plurality of non-monitored facilities 102. Therefore, the power consumption estimation device according to the first embodiment can obtain, as with the conventional technique, the degree of contribution of each target facility 100 and the degrees of contribution of the plurality of non-monitored facilities 102 by applying the total power vector and the state matrices to the regression model.

### Second Embodiment

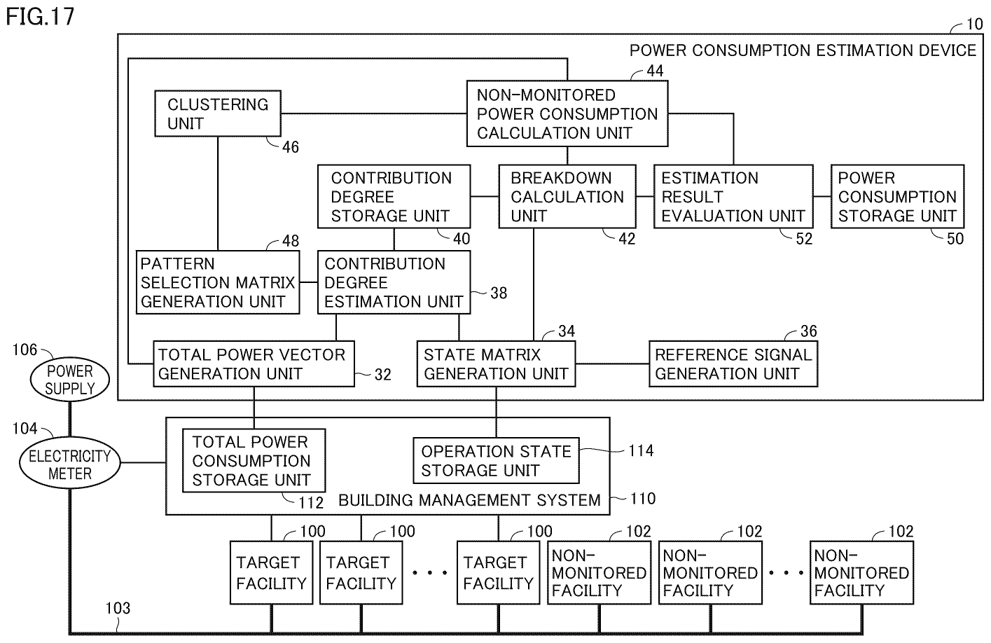

FIG. 17 is a block diagram illustrating a functional configuration of a power consumption estimation device 10 according to a second embodiment. Power consumption estimation device 10 according to the second embodiment is obtained by adding an estimation result evaluation unit 52 to power consumption estimation device 10 according to the first embodiment illustrated in FIG. 2. No description will be given below of parts common to power consumption estimation device 10 according to the first embodiment.

Estimation result evaluation unit 52 evaluates the result of estimating the breakdown of the power consumption using the second regression model shown in expression (7). Specifically, estimation result evaluation unit 52 calculates, for each cluster, an error between the estimated value of total power consumption y, which is the sum of the estimated value of non-monitored power consumption y^{u} and the total value of the estimated values of the power consumption of the first to M-th target facilities 100, and the measured value of total power consumption y. Estimation result evaluation unit 52 compares the calculated error with a preset threshold.

In a case where the error is less than or equal to the threshold for all of the plurality of clusters, estimation result evaluation unit 52 determines that the result of estimating the breakdown of the power consumption is high in accuracy. In this case, estimation result evaluation unit 52 stores the power consumption of the first to M-th target facilities 100 and non-monitored power consumption y^{u}(t) calculated by breakdown calculation unit 42 in power consumption storage unit 50.

On the other hand, in a case where the error is greater than the threshold for at least one of the plurality of clusters, estimation result evaluation unit 52 determines that the result of estimating the breakdown of the power consumption is low in accuracy. In this case, power consumption estimation device 10 determines that the time-series data of non-monitored power consumption y^{u}(t) has not been properly classified in accordance with the operation patterns of the plurality of non-monitored facilities 102. Therefore, power consumption estimation device 10 further performs clustering on a cluster having an error greater than the threshold to divide the cluster into a plurality of clusters.

Specifically, clustering unit 46 classifies (performs clustering on) a plurality of waveforms that fall in the cluster having an error greater than the threshold among the time-series data of non-monitored power consumption y^{u}(t) redefined by non-monitored power consumption calculation unit 44 on the basis of a degree of similarity between the waveforms. The clustering can be performed according to a flow similar to steps S31 and S32 in FIG. 8. Accordingly, the cluster having an error greater than the threshold is subdivided into a plurality of clusters. As a result, the time-series data of non-monitored power consumption y^{u}(t) is classified into clusters larger than the original number of clusters.

When the clustering result in which the date and the cluster number are associated with each other for each waveform is obtained, pattern selection matrix generation unit 48 converts the clustering result into One-Hot representation. Pattern selection matrix generation unit 48 generates a pattern selection matrix by converting the One-Hot encoded clustering result into a diagonal matrix. As illustrated in FIG. 10, the pattern selection matrix has the One-Hot encoded clustering result as a diagonal element. The pattern selection matrix includes a plurality of selection matrices corresponding, on a one-to-one basis, to the plurality of clusters obtained as a result of the subdivision.

The generated pattern selection matrix is input to contribution degree estimation unit 38. Contribution degree estimation unit 38 models the power consumption again using the pattern selection matrix. Accordingly, the second regression model is regenerated.

Contribution degree estimation unit 38 calculates degrees of contribution wᵢ, ^{c1}wⱼ, ^{c2}wⱼ, ^{c3}wⱼ, . . . , and ^{cn}wⱼ by substituting the total power vector, the operation state matrix, and the reference signal matrix into the regenerated second regression model. Note that n is the number of clusters obtained as a result of the subdivision.

Degrees of contribution wᵢ, ^{c1}wⱼ, ^{c2}wⱼ, ^{c3}wⱼ, . . . , and ^{cn}wⱼ by contribution degree estimation unit 38 are stored in contribution degree storage unit 40.

Breakdown calculation unit 42 calculates the power consumption of the i-th target facility 100 by multiplying operation parameter xᵢ of target facility 100 by degree of contribution wᵢ stored in contribution degree storage unit 40. Further, breakdown calculation unit 42 calculates non-monitored power consumption y^{u}(t) by substituting reference signal φⱼ, degrees of contribution wᵢ, ^{c1}wⱼ, ^{c2}wⱼ, ^{c3}wⱼ, . . . , and ^{cn}wⱼ into the following expression (9).

$$\begin{matrix}[ Math . 9 ] & \\ {y}^{u} ( t ) = {\sum }_{j = 1}^{N} ( {S}_{1} \cdot {}^{c 1} {w}_{j} \cdot {∅}_{j} ( t ) ) + {\sum }_{j = 1}^{N} ( {S}_{2} \cdot {}^{c 2} {w}_{j} \cdot {∅}_{j} ( t ) ) + {\sum }_{j = 1}^{N} ( {S}_{3} \cdot {}^{c 3} {w}_{j} \cdot {∅}_{j} ( t ) ) + … + {\sum }_{j = 1}^{N} ( {S}_{n} \cdot {}^{c n} {w}_{j} \cdot {∅}_{j} ( t ) ) & ( 9 )\end{matrix}$$

Accordingly, a breakdown of total power consumption y(t) at sampling timing t is calculated. Estimation result evaluation unit 52 evaluates the result of estimating the breakdown of the power consumption using the regenerated second regression model. As described above, estimation result evaluation unit 52 calculates, for each cluster, an error between the estimated value of total power consumption y, which is the sum of the estimated value of non-monitored power consumption y^{u} and the total value of the estimated values of the power consumption of the first to M-th target facilities 100, and the measured value of total power consumption y. Estimation result evaluation unit 52 compares the calculated error with the preset threshold.

In a case where the error is less than or equal to the threshold for all of the plurality of clusters, estimation result evaluation unit 52 determines that the result of estimating the breakdown of the power consumption is high in accuracy. In this case, estimation result evaluation unit 52 stores the power consumption of the first to M-th target facilities 100 and non-monitored power consumption y^{u}(t) calculated by breakdown calculation unit 42 in power consumption storage unit 50.

On the other hand, in a case where the error is greater than the threshold for at least one of the plurality of clusters, estimation result evaluation unit 52 determines that the result of estimating the breakdown of the power consumption is low in accuracy. In this case, power consumption estimation device 10 determines that the operation patterns of the plurality of non-monitored facilities 102 have not been properly classified, and further performs clustering on the cluster having an error greater than the threshold to divide the cluster into a plurality of clusters.

Power consumption estimation device 10 repeatedly performs the clustering, the regeneration of the second regression model on the basis of the clustering result, the estimation of the breakdown of the power consumption, and the evaluation of the estimation result until the error becomes less than or equal to the threshold for all of the plurality of clusters. Accordingly, the optimum number of clusters can be obtained. As a result, the non-monitored power consumption can be accurately estimated on the basis of the optimum number of operation patterns, thereby allowing an increase in the accuracy of estimating the power consumption of each target facility 100.

### <Operation of Power Consumption Estimation Device>

Next, a flow of power consumption estimation processing performed by power consumption estimation device 10 according to the second embodiment will be described.

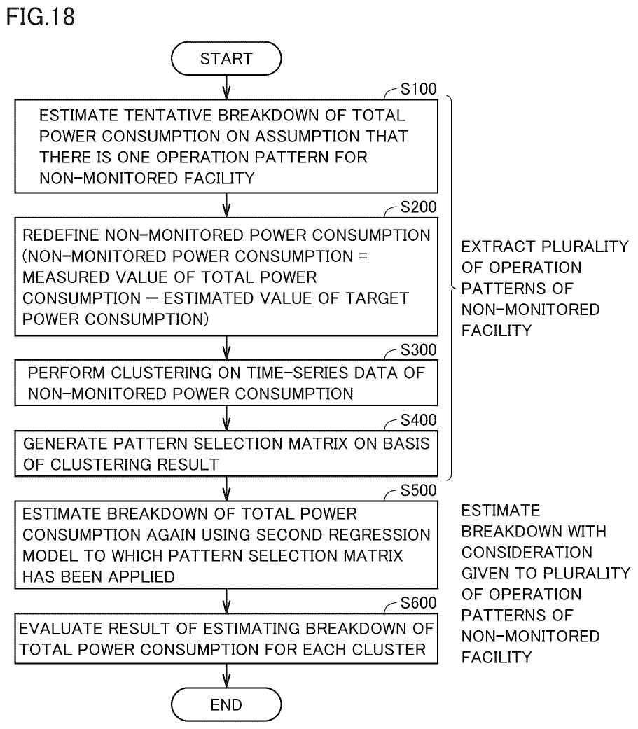

FIG. 18 is a flowchart illustrating an example of the flow of power consumption estimation processing performed by power consumption estimation device 10 according to the second embodiment. The flowchart illustrated in FIG. 18 is obtained by adding a process of step S600 to the flowchart illustrated in FIG. 14.

As illustrated in FIG. 18, when estimating the power consumption of each target facility 100 by means of multiple regression analysis using the generated second regression model in S500, power consumption estimation device 10 evaluates the result of estimating the breakdown of total power consumption y for each cluster (step S600).

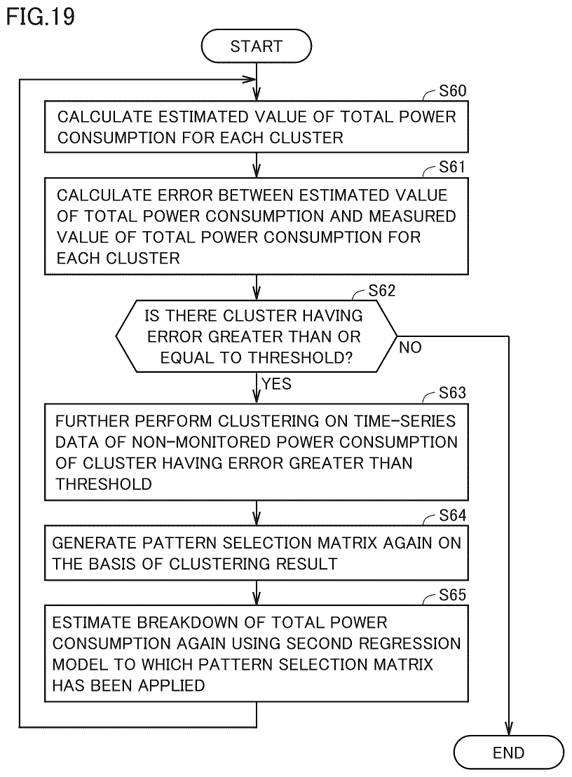

FIG. 19 is a flowchart illustrating a detailed process flow of step S600 in FIG. 18.

As illustrated in FIG. 19, power consumption estimation device 10 calculates the estimated value of total power consumption y by adding up the estimated value of non-monitored power consumption y^{u} and the total value (target power consumption X) of the estimated values of the power consumption of the first to M-th target facilities 100 for each of the plurality of clusters 1 to 3 (step S60).

Next, power consumption estimation device 10 calculates, for each cluster, an error between the estimated value of total power consumption y thus calculated and the measured value of the total power consumption (step S61). Power consumption estimation device 10 compares the calculated error with the predetermined threshold for each cluster (step S62). In S62, power consumption estimation device 10 determines whether or not there is a cluster having an error greater than the threshold among the plurality of clusters 1 to 3. In a case where the error is less than or equal to the threshold for any of the plurality of clusters 1 to 3, it is determined to be NO in S62, and the process of step S600 is brought to an end.

On the other hand, in a case where the error is greater than the threshold for at least one of the plurality of clusters 1 to 3, it is determined to be YES in S62, and the process of step S63 and the subsequent processes are performed.

Specifically, power consumption estimation device 10 extracts a plurality of waveforms that fall into a cluster having an error greater than the threshold from the time-series data of non-monitored power consumption y^{u}(t). Power consumption estimation device 10 further classifies the plurality of extracted waveforms into a plurality of clusters on the basis of a degree of similarity between the waveforms (step S63).

Next, power consumption estimation device 10 generates a pattern selection matrix on the basis of the clustering result obtained in S63 (step S64). In S64, power consumption estimation device 10 generates a predetermined number of pattern selection matrices corresponding to the number of clusters by converting the One-Hot encoded clustering result into a diagonal matrix. Power consumption estimation device 10 generates a plurality of second reference signals corresponding, on a one-to-one basis, to the plurality of clusters obtained as a result of the subdivision on the basis of the generated pattern selection matrix and the plurality of reference signals φⱼ.

Power consumption estimation device 10 corrects the second regression model shown in expression (7) using the generated pattern selection matrix, the total power vector, and the state matrices (operation state matrix and reference signal matrix) to regenerate the second regression model. The regenerated second regression model is a regression model in which the number of operation patterns of the plurality of non-monitored facilities 102 is increased. Power consumption estimation device 10 estimates the power consumption of each target facility 100 by means of multiple regression analysis using the regenerated second regression model (step S65).

When estimating the breakdown of the power consumption in S65, power consumption estimation device 10 returns to the process of S60 and evaluates the result of estimating the breakdown of the total power consumption y again. Power consumption estimation device 10 repeatedly performs the process of S60 to the process of S65 until the error is determined in S62 to be less than or equal to the threshold for all of the plurality of clusters (NO in S62).

As described above, power consumption estimation device 10 according to the second embodiment can perform clustering on the time-series data of the non-monitored power consumption into the optimum number of clusters corresponding to the operation patterns of the plurality of non-monitored facilities 102. It is therefore possible to perform multiple regression analysis using the regression model obtained as a result of properly simulating the operation patterns of the plurality of non-monitored facilities 102, thereby allowing an increase in the accuracy of estimating the non-monitored power consumption. As a result, the accuracy of estimating the power consumption of each target facility can be increased.

### Third Embodiment

In the first and second embodiments described above, the configuration examples have been described in which non-monitored power consumption y^{u}(t) based on the assumption that the plurality of non-monitored facilities 102 have a single operation pattern is simulated using the plurality of reference signals φⱼ. In the third embodiment, a configuration example in which non-monitored power consumption y^{u}(t) is assumed to be constant at all times, and non-monitored power consumption y^{u}(t) is simulated using a constant term will be described.

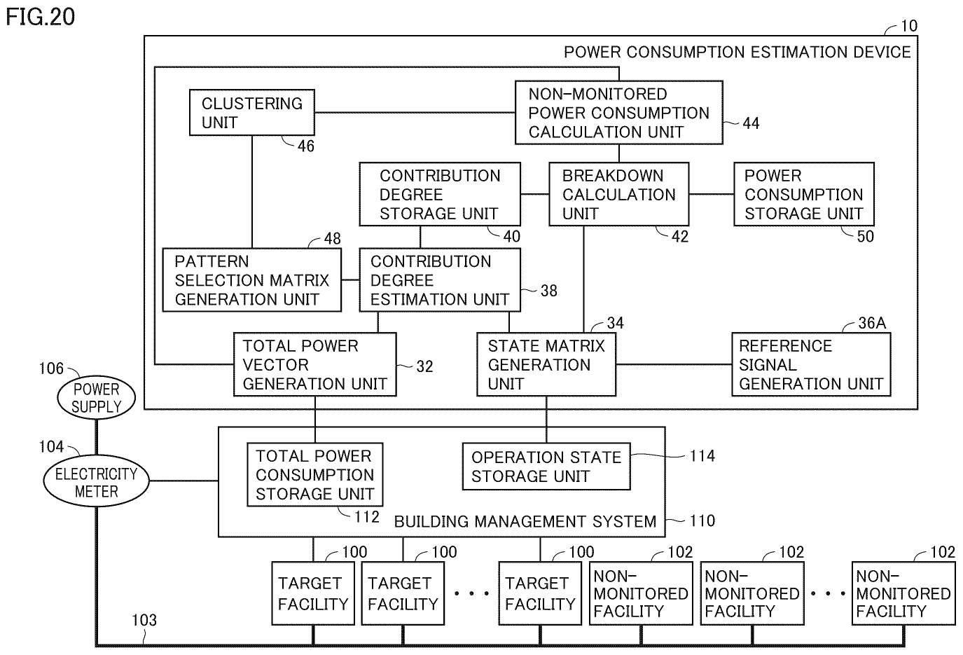

FIG. 20 is a block diagram illustrating a functional configuration of a power consumption estimation device according to the third embodiment. Power consumption estimation device 10 according to the third embodiment is obtained by replacing reference signal generation unit 36 in power consumption estimation device 10 according to the first embodiment illustrated in FIG. 2 with a reference signal generation unit 36A. No description will be given below of parts common to power consumption estimation device 10 according to the first embodiment.

Power consumption estimation device 10 according to the third embodiment represents non-monitored power consumption y^{u}(t) with a known constant term R in the first regression model. Constant term R is set to 0 or a positive value. Reference signal generation unit 36A generates constant term R as the first reference signal. In the third embodiment, total power consumption y(t) at sampling timing t is represented by the following expression (10).

$$\begin{matrix}[ Math . 10 ] & \\ [ \begin{matrix}y ( 1 ) \\ y ( 2 ) \\ ⋮ \\ y ( T )\end{matrix} ] = [ \begin{matrix}{x}_{1} ( 1 ) & … & {x}_{M} ( 1 ) & 1 \\ {x}_{1} ( 2 ) & … & {x}_{M} ( 2 ) & 1 \\ ⋮ & ⋮ & ⋮ & ⋮ \\ {x}_{1} ( T ) & … & {x}_{M} ( T ) & 1\end{matrix} ] [ \text{} \begin{matrix}{w}_{1} \\ ⋮ \\ {w}_{M} \\ R\end{matrix} ] & ( 10 )\end{matrix}$$

Expression (10) can be solved if T>M+1. Then, the power consumption of the i-th target facility 100 at sampling timing t can be calculated by multiplying operation parameter xᵢ(t) of each target facility 100 by calculated degree of contribution wᵢ.

However, since the first regression model of expression (10) handles non-monitored power consumption y^{u}(t) as a constant value, the error between the estimated value of non-monitored power consumption y^{u}(t) and the actual value of non-monitored power consumption y^{u}(t) further increases as compared with the first regression model shown in expression (4).

Therefore, also in the third embodiment, as in the first embodiment, power consumption estimation device 10 redefines non-monitored power consumption y^{u} using the difference between the estimated value of total power consumption y obtained from multiple regression analysis using the first regression model shown in expression (10) and the actual value of total power consumption y measured by electricity meter 104.

Specifically, when the tentative breakdown of total power consumption y(t) at sampling timing t is calculated by breakdown calculation unit 42, non-monitored power consumption calculation unit 44 subtracts the estimated value of target power consumption X(t) from total power consumption y(t) using expression (6) to obtain non-monitored power consumption y^{u}(t). Clustering unit 46 classifies (performs clustering on) the time-series data of redefined non-monitored power consumption y^{u}(t) into similar waveform patterns.

Pattern selection matrix generation unit 48 generates a pattern selection matrix by converting the clustering result into One-Hot representation. Contribution degree estimation unit 38 generates the second regression model shown in expression (7) using the generated pattern selection matrix. Contribution degree estimation unit 38 calculates degrees of contribution wᵢ, ^{c1}wⱼ, ^{c2}wⱼ, and ^{c3}wⱼ by substituting the total power vector, the operation state matrix, and the reference signal matrix into the second regression model. Degrees of contribution wᵢ, ^{c1}wⱼ, ^{c2}wⱼ, and ^{c3}wⱼ calculated by contribution degree estimation unit 38 are stored in contribution degree storage unit 40.

Breakdown calculation unit 42 calculates the power consumption of the i-th target facility 100 by multiplying operation parameter xᵢ of target facility 100 by degree of contribution wᵢ stored in contribution degree storage unit 40. Further, breakdown calculation unit 42 calculates non-monitored power consumption y^{u}(t) by substituting reference signal φⱼ and degrees of contribution ^{c1}wⱼ, ^{c2}wⱼ, and ^{c3}wⱼ into expression (8).

As described above, the power consumption estimation device according to the third embodiment can also produce the same effects as produced by the power consumption estimation device according to the first embodiment.

Note that, for the above-described embodiments, the configurations described in the embodiments are originally intended to form, with neither mismatch nor discrepancy, any desired combination including combinations not mentioned herein.

It should be understood that the embodiments disclosed herein are illustrative in all respects and not restrictive. The scope of the present invention is defined by the claims rather than the above description, and the present invention is intended to include the claims, equivalents of the claims, and all modifications within the scope.

### REFERENCE SIGNS LIST

10: power consumption estimation device, 14: storage device, 16: input device, 18: output device, 22: data bus, 32: total power vector generation unit, 34: state matrix generation unit, 36, 36A: reference signal generation unit, 38: contribution degree estimation unit, 40: contribution degree storage unit, 42: breakdown calculation unit, 44: non-monitored power consumption calculation unit, 46: clustering unit, 48: pattern selection matrix generation unit, 50: power consumption storage unit, 100: target facility, 102: non-monitored facility, 103: power supply line, 104: electricity meter, 106: power supply, 110: building management system, 112: total power consumption storage unit, 114: operation state storage unit

1. A power consumption estimation device to estimate power consumption of each of at least one target facility installed in a predetermined zone, the predetermined zone further having a non-monitored facility installed therein, the power consumption estimation device comprising:
a CPU; and
a memory storing a program,
the CPU executing the program to
acquire time-series data of total power consumption that is power consumption throughout the predetermined zone,
acquire time-series data of an operation parameter obtained by quantifying an operation state of the at least one target facility,
generate at least one first reference signal,
perform multiple regression analysis using a first regression model with the acquired total power consumption as an objective variable and the acquired operation parameter and the at least one first reference signal as explanatory variables to calculate a tentative degree of contribution of each of the at least one target facility to the total power consumption,
estimate power consumption of the target facility by calculating tentative power consumption of the target facility by multiplying the tentative degree of contribution of the target facility by the operation parameter,
calculate time-series data of power consumption of the non-monitored facility by subtracting a total value of the tentative power consumption of the at least one target facility from the time-series data of the total power consumption,
divide the time-series data of the power consumption of the non-monitored facility into a plurality of waveforms at predetermined time intervals and classify the plurality of waveforms into a plurality of clusters on a basis of a degree of similarity between the waveforms, and
generate a plurality of second reference signals corresponding, on a one-to-one basis, to the plurality of clusters,
wherein the performing the multiple regression analysis performs multiple regression analysis using a second regression model with the total power consumption as an objective variable and the operation parameter and the plurality of second reference signals as explanatory variables to determine the degree of contribution of each of the at least one target facility to the total power consumption, and
the estimating the power consumption of the target facility determines the power consumption of the target facility by multiplying the determined degree of contribution of the target facility by the operation parameter.

2. The power consumption estimation device according to claim 1, wherein the estimating the power consumption of the target facility determines the power consumption of each of the at least one target facility at each time to generate a breakdown of the total power consumption at each time.

3. The power consumption estimation device according to claim 1, wherein the dividing the time-series data of the power consumption of the non-monitored facility divides the time-series data of the power consumption of the non-monitored facility into a plurality of waveforms at intervals of 24 hours and classifies the plurality of waveforms into the plurality of clusters set in accordance with a number of operation patterns of the non-monitored facility.

4. The power consumption estimation device according to claim 1, wherein the generating the plurality of second reference signals generates each of the plurality of second reference signals by multiplying at least one reference signal, each of which is represented by a predetermined basis function, by an element that is brought into a selected state for a corresponding cluster and is brought into an unselected state for other clusters.

5. The power consumption estimation device according to claim 1, the CPU further executing the program to evaluate estimation accuracy of the estimating the power consumption of the target facility using the power consumption of the target facility determined by the estimating the power consumption of the target facility.

6. The power consumption estimation device according to claim 5, wherein the evaluating the estimation accuracy calculates an estimated value of the total power consumption by adding up the power consumption of the at least one target facility determined by the estimating the power consumption of the target facility and the power consumption of the non-monitored facility, and evaluates the estimation accuracy of the estimating the power consumption of the target facility on a basis of an error between the estimated value of the total power consumption and a measured value of the total power consumption.

7. The power consumption estimation device according to claim 6, wherein
the dividing the time-series data of the power consumption of the non-monitored facility further classifies a plurality of waveforms falling into a cluster having the error greater than or equal to a threshold into a plurality of clusters on a basis of a degree of similarity between the waveforms,
the generating the plurality of second reference signals regenerates the plurality of second reference signals corresponding, on a one-to-one basis, to the plurality of clusters obtained as a result of the reclassification,
the performing the multiple regression analysis regenerates the second regression model on a basis of the plurality of regenerated second reference signals, and performs multiple regression analysis using the regenerated second regression model to determine the degree of contribution of each of the at least one target facility to the total power consumption, and
the estimating the power consumption of the target facility determines the power consumption of the target facility by multiplying the determined degree of contribution of the target facility by the operation parameter.

8. The power consumption estimation device according to claim 1, wherein the generating the at least one first reference signal generates the at least one first reference signal using at least one predetermined basis function.

9. The power consumption estimation device according to claim 4, wherein the predetermined basis function is a mountain-shaped function or a rectangular function having a single peak per unit time.

10. The power consumption estimation device according to claim 1, wherein the generating the at least one first reference signal generates the first reference signal including a constant term.

11. A power consumption estimation method for estimating power consumption of each of at least one target facility installed in a predetermined zone, the predetermined zone further having a non-monitored facility installed therein, the power consumption estimation method comprising:
acquiring time-series data of total power consumption that is power consumption throughout the predetermined zone;
acquiring time-series data of an operation parameter obtained by quantifying an operation state of the at least one target facility;
generating a first reference signal;
performing multiple regression analysis using a first regression model with the acquired total power consumption as an objective variable and the acquired operation parameter and the first reference signal as explanatory variables to calculate a tentative degree of contribution of each of the at least one target facility to the total power consumption;
calculating tentative power consumption of the target facility by multiplying the tentative degree of contribution of the target facility by the operation parameter;
calculating time-series data of power consumption of the non-monitored facility by subtracting a total value of the tentative power consumption of the at least one target facility from the time-series data of the total power consumption;
dividing the time-series data of the power consumption of the non-monitored facility into a plurality of waveforms at predetermined time intervals and classifying the plurality of waveforms into a plurality of clusters on a basis of a degree of similarity between the waveforms;
generating a plurality of second reference signals corresponding, on a one-to-one basis, to the plurality of clusters;
performing multiple regression analysis using a second regression model with the total power consumption as an objective variable and the operation parameter and the plurality of second reference signals as explanatory variables to determine the degree of contribution of each of the at least one target facility to the total power consumption; and
determining the power consumption of the target facility by multiplying the determined degree of contribution of the target facility by the operation parameter.

12. A non-transitory computer readable storage medium storing a power consumption estimation program for estimating power consumption of at least one target facility installed in a predetermined zone, the predetermined zone further having a non-monitored facility installed therein, the power consumption estimation program causing a computer to execute a process, the process comprising:
acquiring time-series data of total power consumption that is power consumption throughout the predetermined zone;
acquiring time-series data of an operation parameter obtained by quantifying an operation state of the at least one target facility;
generating a first reference signal;
performing multiple regression analysis using a first regression model with the acquired total power consumption as an objective variable and the acquired operation parameter and the first reference signal as explanatory variables to calculate a tentative degree of contribution of each of the at least one target facility to the total power consumption;
calculating tentative power consumption of the target facility by multiplying the tentative degree of contribution of the target facility by the operation parameter;
calculating time-series data of power consumption of the non-monitored facility by subtracting a total value of the tentative power consumption of the at least one target facility from the time-series data of the total power consumption;
dividing the time-series data of the power consumption of the non-monitored facility into a plurality of waveforms at predetermined time intervals and classifying the plurality of waveforms into a plurality of clusters on a basis of a degree of similarity between the waveforms;
generating a plurality of second reference signals corresponding, on a one-to-one basis, to the plurality of clusters;
performing multiple regression analysis using a second regression model with the total power consumption as an objective variable and the operation parameter and the plurality of second reference signals as explanatory variables to determine the degree of contribution of each of the at least one target facility to the total power consumption; and
determining the power consumption of the target facility by multiplying the determined degree of contribution of the target facility by the operation parameter.
